(19) United States
(12) Patent Application Publication
(10) Pub. No.: US 2020/0099009 A1
(43) Pub. Date: Mar. 26, 2020

(54) MULTILAYER FILM FOR ORGANIC ELECTROLUMINESCENT DISPLAY DEVICES, AND POLARIZING PLATE, ANTI-REFLECTION FILM AND ORGANIC ELECTROLUMINESCENT DISPLAY DEVICE, EACH OF WHICH COMPRISES SAME

(71) Applicant: ZEON CORPORATION, Chiyoda-ku, Tokyo (JP)

(72) Inventors: Kenji YODA, Tokyo (JP); Toshihide MURAKAMI, Tokyo (JP); Masaru KIKUKAWA, Tokyo (JP)

(73) Assignee: ZEON CORPORATION, Chiyoda-ku, Tokyo (JP)

(21) Appl. No.: 16/495,578

(22) PCT Filed: Mar. 19, 2018
(86) PCT No.: PCT/JP2018/010884

§ 371 Date: Sep. 19, 2019

(30) Foreign Application Priority Data
Mar. 30, 2017 (JP) 2017-067773

(51) Int. Cl. H01L 51/52; G02B 5/30

(52) U.S. Cl. CPC H01L 51/5253; G02B 5/3033; H01L 51/5281

(57) ABSTRACT

A multilayer film for an organic electroluminescent display device, including at least one substrate layer containing a crystallizable polymer, a barrier layer, and an electroconductive layer, wherein at least one of the barrier layer and the electroconductive layer is in direct contact with the substrate layer.

### FIELD

The present invention relates to a multilayer film for an organic electroluminescent display device, and a polarizing plate, an antireflection film and an organic electroluminescent display device which include the multilayer film.

### BACKGROUND

An organic electroluminescent display device (hereinafter appropriately referred to as an “organic EL display device”) may comprise a barrier film including a barrier layer in order to prevent deterioration of a light-emitting layer thereof and its surrounding layers. This barrier film is usually a multilayer film including a substrate layer and a barrier layer provided on the substrate layer (see Patent Literature 1).

Further, an organic EL display device including an input/output unit such as a touch panel may include an electroconductive film including an electroconductive layer such as an input/output electrode layer. Such an electroconductive film is usually a multilayer film comprising a substrate layer and an electroconductive layer provided on the substrate layer (see Patent Literature 2).

### CITATION LIST

### Patent Literature

Patent Literature 1: Japanese Patent Application Laid-Open No. 2011-201043 A

Patent Literature 2: International Publication No. 2016/067893

### SUMMARY

### Technical Problem

In the above-described multilayer film such as a barrier film or an electroconductive film, a resin layer containing a polymer is often used as a substrate layer. However, such a multilayer film including a resin layer as a substrate layer may be poor in solvent resistance and grease resistance.

In light of the above-described problem, it is an object of the present invention to provide a multilayer film for an organic EL display device which has excellent solvent resistance and grease resistance and which includes a barrier layer and an electroconductive layer; and a polarizing plate, an antireflection film, and an organic EL display device which include the multilayer film.

### Solution to Problem

<1> A multilayer film for an organic electroluminescent display device, comprising at least one substrate layer containing a crystallizable polymer, a barrier layer, and an electroconductive layer, wherein

at least one of the barrier layer and the electroconductive layer is in direct contact with the substrate layer.

<2> The multilayer film according to <1>, wherein both the barrier layer and the electroconductive layer are in direct contact with the substrate layer.
<3> The multilayer film according to <1> or <2>, wherein a melting point of the crystallizable polymer is 250° C. or higher.
<4> The multilayer film according to any one of <1> to <3>, wherein the crystallizable polymer contains an alicyclic structure.
<5> The multilayer film according to any one of <1> to <4>, wherein the crystallizable polymer is a hydrogenated product of a ring-opening polymer of dicyclopentadiene.
<6> The multilayer film according to any one of <1> to <5>, wherein the crystallizable polymer has a positive intrinsic birefringence value.
<7> The multilayer film according to any one of <1> to <6>, wherein the multilayer film includes one or more inorganic barrier layers as the barrier layer.
<8> The multilayer film according to any one of <1> to <7>, wherein a water vapor transmission rate of the multilayer film is 0.01 g/(m²·day) or less.
<9> The multilayer film according to any one of <1> to <8>, wherein the multilayer film includes one or more organic electroconductive layers as the electroconductive layer.
<10> The multilayer film according to <9>, wherein the organic electroconductive layer contains polyethylenedioxythiophene.
<11> The multilayer film according to any one of <1> to <10>, wherein the multilayer film includes one or more inorganic electroconductive layers as the electroconductive layer.
<12> The multilayer film according to <11>, wherein the inorganic electroconductive layer contains at least one selected from the group consisting of Ag, Cu, ITO, and metallic nanowires.
<13> The multilayer film according to any one of <1> to <12>, wherein, when the substrate layer is heated at 150° C. for 1 hour, an absolute value of a thermal size change rate in a plane of a film of the substrate layer is 1% or less.
<14> The multilayer film according to any one of <1> to <13>, wherein

the multilayer film includes a high-Re substrate layer, of which an in-plane retardation Re at a temperature of 23° C. and a measurement wavelength of 590 nm is 100 nm or more and 300 nm or less, as the substrate layer, and

an absolute value of photoelastic coefficient of the high-Re substrate layer is 2.0×10⁻¹¹ Pa⁻¹ or less.

<15> The multilayer film according to <14>, wherein

the multilayer film has a long-length shape, and

a slow axis of the high-Re substrate layer is present in an oblique direction relative to a lengthwise direction of the multilayer film.

<16> The multilayer film according to <14> or <15>, wherein a birefringence Δn of the high-Re substrate layer is 0.0010 or more.
<17> The multilayer film according to any one of <1> to <16>, wherein

the multilayer film includes a low-Re substrate layer, of which an in-plane retardation Re at a temperature of 23° C. and a measurement wavelength of 590 nm is less than 100 nm, as the substrate layer, and

an absolute value of photoelastic coefficient of the low-Re substrate layer is 2.0×10⁻¹¹ Pa⁻¹ or less.

<18> The multilayer film according to <17>, wherein

the multilayer film has a long-length shape,

the multilayer film includes a long-length ¼ wave film layer, and

a slow axis of the ¼ wave film layer is present in an oblique direction relative to a lengthwise direction of the multilayer film.

<19> A polarizing plate comprising the multilayer film according to any one of <1> to <18>, and a linear polarizing film.
<20> The polarizing plate according to <19>, wherein the multilayer film functions as a protective layer for the linear polarizing film.
<21> The polarizing plate according to <19> or <20>, wherein

the multilayer film includes a λ/4 substrate layer having an in-plane retardation of ¼ wavelength as the substrate layer,

the polarizing plate includes the linear polarizing film, the electroconductive layer, the λ/4 substrate layer, and the barrier layer in this order, and

an angle formed between a polarized light transmission axis of the linear polarizing film and a slow axis of the λ/4 substrate layer is 35° or more and 55° or less.

<22> The polarizing plate according to <19> or <20>, wherein

the multilayer film includes a λ/4 substrate layer having an in-plane retardation of ¼ wavelength and a λ/2 substrate layer having an in-plane retardation of ½ wavelength as the substrate layer,

the polarizing plate includes the linear polarizing film, the λ/2 substrate layer, the electroconductive layer, the λ/4 substrate layer, and the barrier layer in this order,

an angle formed between a polarized light transmission axis of the linear polarizing film and a slow axis of the λ/2 substrate layer is 10° or more and 20° or less, or 70° or more and 80° or less, and

an angle formed between the slow axis of the λ/2 substrate layer and a slow axis of the λ/4 substrate layer is 55° or more and 65° or less.

<23> The polarizing plate according to <22>, wherein

the λ/2 substrate layer and the electroconductive layer are in direct contact with each other, and

the λ/4 substrate layer and the barrier layer are in direct contact with each other.

<24> The polarizing plate according to <22> or <23>, wherein

the λ/4 substrate layer and the electroconductive layer are in direct contact with each other, and

the λ/4 substrate layer and the barrier layer are in direct contact with each other.

<25> The polarizing plate according to <19> or <20>, wherein

the multilayer film includes a λ/4 substrate layer having an in-plane retardation of ¼ wavelength and a λ/2 substrate layer having an in-plane retardation of ½ wavelength as the substrate layer,

the polarizing plate includes the linear polarizing film, the electroconductive layer, the λ/2 substrate layer, the barrier layer, and the λ/4 substrate layer in this order,

an angle formed between a polarized light transmission axis of the linear polarizing film and a slow axis of the λ/2 substrate layer is 10° or more and 20° or less, or 70° or more and 80° or less, and

an angle formed between the slow axis of the λ/2 substrate layer and a slow axis of the λ/4 substrate layer is 55° or more and 65° or less.

<26> The polarizing plate according to <25>, wherein

the λ/2 substrate layer and the electroconductive layer are in direct contact with each other, and

the λ/4 substrate layer and the barrier layer are in direct contact with each other.

<27> The polarizing plate according to <25> or <26>, wherein

the λ/2 substrate layer and the electroconductive layer are in direct contact with each other, and

the λ/2 substrate layer and the barrier layer are in direct contact with each other.

<28> The polarizing plate according to <19> or <20>, wherein

the multilayer film includes a λ/4 substrate layer having an in-plane retardation of ¼ wavelength and a λ/2 substrate layer having an in-plane retardation of ½ wavelength as the substrate layer,

the polarizing plate includes the linear polarizing film, the electroconductive layer, the λ/2 substrate layer, the λ/4 substrate layer, and the barrier layer in this order,

an angle formed between a polarized light transmission axis of the linear polarizing film and a slow axis of the λ/2 substrate layer is 10° or more and 20° or less, or 70° or more and 80° or less, and

an angle formed between the slow axis of the λ/2 substrate layer and a slow axis of the λ/4 substrate layer is 55° or more and 65° or less.

<29> The polarizing plate according to <19> or <20>, wherein the multilayer film include a first electroconductive layer and a second electroconductive layer as the electroconductive layer.
<30> The polarizing plate according to <29>, wherein

the multilayer film includes a λ/4 substrate layer having an in-plane retardation of ¼ wavelength and a λ/2 substrate layer having an in-plane retardation of ½ wavelength as the substrate layer,

the polarizing plate includes the linear polarizing film, the first electroconductive layer, the λ/2 substrate layer, the second electroconductive layer, the λ/4 substrate layer, and the barrier layer in this order,

an angle formed between a polarized light transmission axis of the linear polarizing film and a slow axis of the λ/2 substrate layer is 10° or more and 20° or less, or 70° or more and 80° or less, and

an angle formed between the slow axis of the λ/2 substrate layer and a slow axis of the λ/4 substrate layer is 55° or more and 65° or less.

<31> The polarizing plate according to <30>, wherein

the λ/2 substrate layer and the first electroconductive layer are in direct contact with each other,

the λ/4 substrate layer and the second electroconductive layer are in direct contact with each other, and

the λ/4 substrate layer and the barrier layer are in direct contact with each other.

<32> The polarizing plate according to <30> or <31>, wherein

the λ/2 substrate layer and the first electroconductive layer are in direct contact with each other,

the λ/2 substrate layer and the second electroconductive layer are in direct contact with each other, and

the λ/4 substrate layer and the barrier layer are in direct contact with each other.

<33> The polarizing plate according to any one of <22> to <28> and <30> to <32>, wherein

the polarizing plate has a long-length shape,

the polarized light transmission axis of the linear polarizing film is parallel to a lengthwise direction of the polarizing plate, and

the slow axis of the λ/2 substrate layer or the λ/4 substrate layer is present in an oblique direction relative to the lengthwise direction of the polarizing plate.

<34> An antireflection film comprising the polarizing plate according to any one of <19> to <33>, wherein

a ratio R₀/R_{10(0deg)} of reflectivity R₀ at an incident angle of 0° relative to reflectivity R_{10(180deg)} at an azimuth angle of 0° and an incident angle of 10° is 0.95 or more and 1.05 or less, and

a ratio R₀/R_{10(180deg)} of the reflectivity R₀ at the incident angle of 0° relative to reflectivity R_{10(180deg)} at an azimuth angle of 180° and an incident angle of 10° is 0.95 or more and 1.05 or less.

<35> An organic electroluminescent display device comprising the polarizing plate according to any one of <19> to <33>.
<36> The organic electroluminescent display device according to <35>, comprising a cover layer formed of a resin.

### Advantageous Effects of Invention

According to the present invention, it is possible to provide a multilayer film for an organic EL display device which has excellent solvent resistance and grease resistance and which includes a barrier layer and an electroconductive layer; and a polarizing plate, an antireflection film, and an organic EL display device which include the multilayer film.

### BRIEF DESCRIPTION OF DRAWINGS

FIG. 1 is a cross-sectional view schematically illustrating a polarizing plate as a first embodiment of the present invention.

FIG. 2 is a cross-sectional view schematically illustrating a polarizing plate as a second embodiment of the present invention.

FIG. 3 is a cross-sectional view schematically illustrating a polarizing plate as a third embodiment of the present invention.

FIG. 4 is a cross-sectional view schematically illustrating a polarizing plate as a fourth embodiment of the present invention.

FIG. 5 is a cross-sectional view schematically illustrating a polarizing plate as a fifth embodiment of the present invention.

FIG. 6 is a cross-sectional view schematically illustrating a polarizing plate as a sixth embodiment of the present invention.

FIG. 7 is a cross-sectional view schematically illustrating a polarizing plate as a seventh embodiment of the present invention.

FIG. 8 is a cross-sectional view schematically illustrating a polarizing plate as an eighth embodiment of the present invention.

FIG. 9 is a cross-sectional view schematically illustrating a polarizing plate as a ninth embodiment of the present invention.

FIG. 10 is a cross-sectional view schematically illustrating a polarizing plate as a tenth embodiment of the present invention.

FIG. 11 is a perspective view schematically illustrating a jig used in Examples according to the present invention and Comparative Examples.

FIG. 12 is a front view schematically illustrating the jig shown in FIG. 11 which is in close contact with a film piece.

### DESCRIPTION OF EMBODIMENTS

Hereinafter, the present invention will be described in detail with reference to embodiments and examples. However, the present invention is not limited to the following embodiments and examples, and may be freely modified for implementation without departing from the scope of claims of the present invention and the scope of their equivalents.

In the following description, an in-plane retardation Re of a layer is a value represented by “Re=(nx−ny)×d” unless otherwise specified. A thickness-direction retardation Rth of a layer is a value represented by “Rth=[{(nx+ny)/2}−nz]×d” unless otherwise specified. A birefringence Δn of a layer is a value represented by “Δn=nx−ny” unless otherwise specified. Herein, nx represents a refractive index in a direction in which the maximum refractive index is given among directions perpendicular to the thickness direction of the layer (in-plane directions). ny represents a refractive index in a direction, among the above-mentioned in-plane directions of the layer, perpendicular to the direction giving nx. nz represents a refractive index in the thickness direction of the layer. d represents the thickness of the layer. The measurement temperature is 23° C. and the measurement wavelength is 590 nm, unless otherwise specified.

In the following description, a “long-length” film refers to a film with the length that is 5 times or more the width, and preferably a film with the length that is 10 times or more the width, and specifically refers to a film having a length that allows a film to be wound up into a rolled shape for storage or transportation. The upper limit of the length thereof is not particularly limited, and is usually 100,000 times or less the width.

In the following description, the lengthwise direction of the long-length film is usually parallel to a film conveyance direction in the production line. Further, an MD direction (machine direction) is a film conveyance direction in the production line, and is usually parallel to the lengthwise direction of the long-length film. Further, a TD direction (traverse direction) is a direction parallel to the film surface and perpendicular to the MD direction, and is usually parallel to the width direction of the long-length film.

In the following description, a slow axis of a layer represents a slow axis in the plane of the layer, unless otherwise specified.

In the following description, an angle formed between optical axes (polarized light transmission axis, polarized light absorption axis, slow axis, etc.) of respective layers in a member including a plurality of layers represents an angle when the layers are viewed in the thickness direction, unless otherwise specified.

In the following description, a direction of an element being “parallel”, “perpendicular” or “orthogonal” may allow an error within the range of not impairing the advantageous effects of the present invention, for example, within a range of ±5°, unless otherwise specified.

In the following description, a front direction of a certain surface means the normal direction of the surface, specifically, a direction at the polar angle 0° and the azimuth angle 0° of the surface, unless otherwise specified. Furthermore, an inclined direction of a certain surface means a direction which is neither parallel nor perpendicular to the surface, specifically, a direction in a polar angle range of larger than 0° and smaller than 90° of the surface, unless otherwise specified.

In the following description, a “polarizing plate”, and a “wave plate” include not only a rigid member, but also a flexible member such as a resin film, unless otherwise specified.

[1. Summary of Multilayer Film]

The multilayer film according to the present invention is a multilayer film for an organic EL display device, and includes a substrate layer, a barrier layer, and an electroconductive layer. At least one of the barrier layer and the electroconductive layer is in direct contact with the substrate layer. The substrate layer contains a crystallizable polymer. Such a multilayer film has excellent solvent resistance, and is therefore less likely to break even when a solvent is attached thereto in the process of producing organic EL display devices. Further, this multilayer film has excellent grease resistance, and is therefore less likely to deteriorate due to grease even when grease is attached thereto through contact with humans.

The multilayer film includes at least one substrate layer. Therefore, the number of substrate layers may be one or two or more. When the number of substrate layers is two or more, a substrate layer that is in direct contact with a barrier layer and a substrate layer that is in direct contact with an electroconductive layer may be the same or different from each other. Further, the multilayer film includes at least one barrier layer.

Therefore, the number of barrier layers may be one or two or more. Further, the multilayer film includes at least one electroconductive layer. Therefore, the number of electroconductive layers may be one or two or more.

That two certain layers are “in direct contact” with each other refers to that no layer is interposed between these layers that are in direct contact with each other.

In the multilayer film according to the present invention, both the barrier layer and the electroconductive layer are preferably in direct contact with the substrate layer. This makes it possible to reduce the thickness of the multilayer film.

[2. Substrate Layer]

The substrate layer is a layer containing a crystallizable polymer. Therefore, the substrate layer is usually a resin layer formed of a resin containing a crystallizable polymer. In the following description, a resin containing a crystallizable polymer may be referred to as a “crystallizable resin”.

The crystallizable polymer is a polymer having crystallizability. Herein, the “polymer having crystallizability” refers to a polymer having a melting point Tm. The polymer having a melting point Tm refers to a polymer of which the melting point Tm can be observed by a differential scanning calorimeter (DSC).

Examples of the crystallizable polymer may include a crystallizable polymer containing an alicyclic structure, and a crystallizable polystyrene-based polymer (see Japanese Patent Application Laid-Open No. 2011-118137 A). Among these, a crystallizable polymer containing an alicyclic structure is preferable because of its excellent transparency, low hygroscopicity, size stability, and light-weight properties.

The polymer containing an alicyclic structure is a polymer that has an alicyclic structure in its molecule and can be obtained by a polymerization reaction using a cyclic olefin as a monomer, or a hydrogenated product thereof. Examples of the alicyclic structure may include a cycloalkane structure and a cycloalkene structure. Among these, a cycloalkane structure is preferable because it is easy to obtain a substrate layer having excellent properties such as thermal stability. The number of carbon atoms contained in one alicyclic structure is preferably 4 or more, and more preferably 5 or more, and is preferably 30 or less, more preferably 20 or less, and particularly preferably 15 or less. When the number of carbon atoms contained in one alicyclic structure falls within the aforementioned range, mechanical strength, heat resistance, and moldability of the crystallizable resin are highly balanced.

In the crystallizable polymer, the ratio of the structural unit having an alicyclic structure relative to all structural units is preferably 30% by weight or more, more preferably 50% by weight or more, and particularly preferably 70% by weight or more. When the ratio of the structural unit having an alicyclic structure is increased as described above, heat resistance can be enhanced.

The rest of the crystallizable polymer other than the structural unit having the alicyclic structure is not particularly limited, and may be appropriately selected depending on the purposes of use.

Preferable examples of the crystallizable polymer may include the following polymer (α) to polymer (δ). Among these, the polymer (β) is particularly preferable because a substrate layer having excellent heat resistance can be easily obtained therewith.

Polymer (α): a ring-opening polymer of a cyclic olefin monomer having crystallizability

Polymer (β): a hydrogenated product of the polymer (a) having crystallizability

Polymer (γ): an addition polymer of a cyclic olefin monomer having crystallizability

Polymer (δ): a hydrogenated product and the like of the polymer (γ) having crystallizability

More specifically, the crystallizable polymer is preferably a ring-opening polymer of dicyclopentadiene having crystallizability and a hydrogenated product of a ring-opening polymer of dicyclopentadiene having crystallizability, and is particularly preferably a hydrogenated product of a ring-opening polymer of dicyclopentadiene having crystallizability. Herein, the ring-opening polymer of dicyclopentadiene refers to a polymer in which the ratio of the structural unit derived from dicyclopentadiene relative to the total structural units is usually 50% by weight or more, preferably 70% by weight or more, more preferably 90% by weight or more, and still more preferably 100% by weight.

The crystallizable polymer containing an alicyclic structure preferably has a syndiotactic structure, and more preferably has a high degree of syndiotactic stereoregularity. By having such a structure, the crystallizability of the polymer can be enhanced, so that the tensile elastic modulus can be particularly increased. The degree of syndiotactic stereoregularity of a crystallizable polymer may be represented by the ratio of racemo⋅diad of the crystallizable polymer. The specific ratio of the racemo⋅diad is preferably 51% or more, more preferably 60% or more, and particularly preferably 70% or more. The ratio of racemo⋅diad may be measured by the method described in the example section.

As the crystallizable polymer, one type thereof may be solely used, and two or more types thereof may also be used in combination at any ratio.

The crystallizable polymer may not have crystallized prior to the production of the multilayer film. However, after the production of the multilayer film of the present invention, the crystallizable polymer contained in the multilayer film can usually have a high crystallization degree because it has crystallized. The range of the specific crystallization degree may be appropriately selected according to the desired performance, and is preferably 10% or more, more preferably 15% or more, and particularly preferably 30% or more. When the crystallization degree is equal to or larger than the lower limit value of the aforementioned range, high heat resistance and chemical resistance can be imparted to the substrate layer.

The crystallization degree of a polymer may be measured by an X-ray diffraction method.

The weight-average molecular weight (Mw) of the crystallizable polymer is preferably 1,000 or more, and more preferably 2,000 or more, and is preferably 1,000,000 or less, and more preferably 500,000 or less. The crystallizable polymer having such a weight-average molecular weight has excellent balance between molding processability and heat resistance.

The molecular weight distribution (Mw/Mn) of the crystallizable polymer is preferably 1.0 or more, and more preferably 1.5 or more, and is preferably 4.0 or less, and more preferably 3.5 or less. Herein, Mn represents a number-average molecular weight. The crystallizable polymer having such a molecular weight distribution is excellent in molding processability.

The weight-average molecular weight (Mw) and the molecular weight distributions (Mw/Mn) of a polymer may be measured as a polystyrene-equivalent value by gel permeation chromatography (GPC) using tetrahydrofuran as a developing solvent.

The melting point Tm of the crystallizable polymer is preferably 200° C. or higher, more preferably 230° C. or higher, and particularly preferably 250° C. or higher, and is preferably 290° C. or lower. By using a crystallizable polymer having such a melting point Tm, it is possible to obtain a substrate layer having a still better balance between moldability and heat resistance.

The glass transition temperature Tg of the crystallizable polymer is not particularly limited, and is usually 85° C. or higher and usually 170° C. or lower.

The crystallizable polymer preferably has a positive intrinsic birefringence value. A polymer having a positive intrinsic birefringence value means a polymer in which the refractive index in the stretching direction is greater than the refractive index in the direction orthogonal thereto. The intrinsic birefringence value may be calculated from the dielectric constant distribution. By employing a crystallizable polymer having a positive intrinsic birefringence value, it is possible to easily obtain a substrate layer having favorable properties such as a high orientation regulating force, a high strength, a low cost, a low thermal size change rate.

The method for producing the crystallizable polymer may be any method. For example, a crystallizable polymer containing an alicyclic structure may be produced by the method described in International Publication No. 2016/067893.

The ratio of the crystallizable polymer in the crystallizable resin is preferably 50% by weight or more, more preferably 70% by weight or more, and particularly preferably 90% by weight or more. When the ratio of the crystallizable polymer is equal to or more than the lower limit value of the aforementioned range, heat resistance of the substrate layer can be enhanced.

The crystallizable resin may contain optional components in addition to the crystallizable polymer. Examples of the optional components may include an antioxidant such as a phenol-based antioxidant, a phosphorus-based antioxidant, and a sulfur-based antioxidant; a light stabilizer such as a hindered amine-based light stabilizer; a wax such as a petroleum-based wax, a Fischer-Tropsch wax, and a polyalkylene wax; a nucleating agent such as a sorbitol-based compound, a metal salt of an organophosphate, a metal salt of an organocarboxylic acid, kaolin and talc; a fluorescent brightener such as a diaminostilbene derivative, a coumarine derivative, an azole derivative (for example, a benzoxazole derivative, a benzotriazole derivative, a benzimidazole derivative, and a benzothiazole derivative), a carbazole derivative, a pyridine derivative, a naphthalic acid derivative, and an imidazolone derivative; an ultraviolet absorber such as a benzophenone-based ultraviolet absorber, a salicylic acid-based ultraviolet absorber, and a benzotriazole-based ultraviolet absorber; an inorganic filler such as talc, silica, calcium carbonate, and glass fiber; a colorant; a flame retardant; a flame retardant aid; an antistatic agent; a plasticizer; a near infrared absorber; a lubricant; a filler, and an optional polymer other than the crystallizable polymer, such as a soft polymer. As the optional components, one type thereof may be solely used, and two or more types thereof may also be used in combination at any ratio.

The substrate layer is preferably a layer having a excellent transparency. Specifically, the total light transmittance of the substrate layer is preferably 80% or more, more preferably 85% or more, and particularly preferably 88% or more. The total light transmittance may be measured in the wavelength range of 400 nm to 700 nm using an ultraviolet-visible spectrometer.

The substrate layer preferably has a small internal haze. Herein, the haze of the layer usually includes a haze caused by light scattering due to minute irregularities on the surface of the layer and a haze caused by an internal refractive index distribution. The internal haze refers to a haze that is obtained by subtracting the haze caused by light scattering due to minute irregularities on the surface of the layer from the normal haze. Such internal haze may be measured in the manner described in the example section. The internal haze of the substrate layer is preferably 3% or less, more preferably 2% or less, more preferably 1% or less, and particularly preferably 0.5% or less. The internal haze of the substrate layer is ideally 0%, and the lower limit may be more than 0%.

The absolute value of photoelastic coefficient of the substrate layer is preferably 2.0×10⁻¹¹ Pa⁻¹ or less, more preferably 1.0×10⁻¹¹ Pa⁻¹ or less, and particularly preferably 6.0×10⁻¹² Pa⁻¹ or less. The photoelastic coefficient is a value that indicates the stress dependence of birefringence caused by the application of stress. Birefringence (difference between refractive indexes) Δn, stress σ, and photoelastic coefficient C have a relationship such that birefringence Δn is determined as a product of stress σ and photoelastic coefficient C (Δn=C·σ). When the absolute value of the photoelastic coefficient is equal to or less than the above-described upper limit, the substrate layer can exhibit excellent optical performance even when subjected to impact or deformed to fit with a display device having a curved display surface. The photoelastic coefficient may be measured using a photoelastic coefficient measuring device (manufactured by Uniopt Co., Ltd., PHEL-20A) under conditions of a temperature of 20° C.±2° C. and a humidity of 60±5%. The photoelastic coefficient may also be determined also by producing a load-Δn curve and determining the photoelastic coefficient as the slope of the curve. This load-Δn curve may be produced by performing an operation of measuring values of birefringence Δn while applying different loads of 50 g to 150 g onto a film. The birefringence value Δn may also be determined by measuring the in-plane retardation of a film using a retardation measuring device (manufactured by Oji Scientific Instruments, “KOBRA-21ADH”) and dividing the in-plane retardation by the thickness of the film. The lower limit value of photoelastic coefficient of the substrate layer is not particularly limited, and may be, for example, 0.5×10⁻¹² Pa⁻¹ or more.

It is preferable that the substrate layer has a nature such that, upon heating of the substrate, the absolute value of a thermal size change rate in a plane of the film is at a certain small value. More specifically, when the substrate layer is heated at 150° C. for 1 hour, the absolute value of a thermal size change rate in the plane of the film is preferably 1% or less, more preferably 0.5% or less, and even more preferably 0.1% or less. The lower limit of absolute value of the thermal size change rate is not particularly limited, and may ideally be 0%. The substrate layer usually shrinks in a hot environment, and therefore the above-described thermal size change rate is usually a negative value. When the absolute value of thermal size change rate of the substrate layer is such a small value, it is possible to prevent the occurrence of defects resulting from the formation of a barrier layer, and thereby a multilayer film having high quality can be easily produced. Further, when such a multilayer film is used as a component of an organic EL display device, the organic EL display device can exhibit high durability and excellent optical performance.

The thermal size change rate of a film such as a substrate layer may be measured by the following method.

A square sample film having a size of 150 mm×150 mm is cut out from a film in an environment at a room temperature of 23° C. The sample film is heated in an oven at 150° C. for 60 minutes and cooled to 23° C. (room temperature). Then, the lengths of four edges and the lengths of two diagonal lines of the sample film are measured.

On the basis of the measured length of each of the four edges, the thermal size change rate of the sample film is calculated by the following formula (I). In the formula (I), L_{A} (mm) represents the length of edge of the sample film after heating.

Thermal size change rate (%)=[(L_{A}−150)/150]×100 (I)

Further, on the basis of the measured lengths of the two diagonal lines, the thermal size change rate of the sample film is calculated by the following formula (II). In the formula (II), L_{D} (mm) represents the length of diagonal line of the sample film after heating.

Thermal size change rate (%)=[(L_{D}−212.13)/212.13]×100 (II)

Then, the value having maximum absolute value among the obtained six calculated values of the thermal size change rate is adopted as the thermal size change rate of the film. The thermal size change rate obtained by such measurement can substantially be the largest thermal size change rate among thermal size change rates measured in all in-plane directions.

The substrate layer preferably has excellent chemical resistance. More specifically, it is preferable that the substrate layer is less likely to fracture, crack, whiten, discolor, swell, or deform (e.g., wave) even when immersed in 35% hydrochloric acid, 30% sulfuric acid, and a 30% aqueous sodium hydroxide solution. The chemical resistance of the substrate layer may be measured by a method that will be described in the example section.

The substrate layer preferably has excellent solvent resistance. More specifically, it is preferable that the substrate layer is less likely to fracture, crack, whiten, discolor, swell, or deform (e.g., wave) even when immersed in cyclohexane, normal hexane, methyl ethyl ketone, chloroform, and isopropanol. The solvent resistance of the substrate layer may be measured by a method that will be described in the example section.

The substrate layer preferably has excellent grease resistance. More specifically, it is preferable that the substrate layer is less likely to fracture, crack, whiten, discolor, swell, or deform (e.g., wave) even when immersed in oleic acid or coming into contact with Vaseline. The grease resistance of the substrate layer may be measured by a method that will be described in the example section.

A resin layer in prior art consisting of a crystallizable resin tends to be poor in folding resistance. However, the substrate layer used in the present invention preferably has excellent folding resistance. More specifically, when the substrate layer is subjected to a tension-free U-shape folding test for planar objects, the number of test cycles upto fracture is preferably 50,000 cycles or more, more preferably 100,000 cycles or more, particularly preferably 200,000 cycles or more. The tension-free U-shape folding test for planar objects herein refers to a test in which a rectangular film is horizontally placed and repeatedly folded so as to project downward in the gravity direction by bringing the parallel two edges of the film close to each other in the horizontal direction without applying a load to the thickness direction of the film. The number of test cycles upto fracture in the tension-free U-shape folding test for planar objects may be measured by a method that will be described in the example section.

A resin layer in prior art consisting of a crystallizable resin tends to be poor in bend resistance. However, the substrate layer used in the present invention preferably has excellent bend resistance. More specifically, when the substrate layer is subjected to a reciprocating repeated bending test at a bending radius of 5 mm, a bending angle of ±135°, and a load of 2 N, the number of test cycles upto fracture is preferably 100,000 cycles or more, and more preferably 200,000 cycles or more. The number of test cycles upto fracture in the reciprocating repeated bending test may be measured by a method that will be described in the example section.

The substrate layer having such excellent folding resistance and bend resistance is suitable as a substrate used in the multilayer film according to the present invention including an electroconductive layer and a barrier layer.

The in-plane retardation Re of the substrate layer may be small. For example, the in-plane retardation Re of the substrate layer at a temperature of 23° C. and a measurement wavelength of 590 nm may be less than 100 nm. In the following description, the substrate layer having such a small in-plane retardation Re may be referred to as a “low-Re substrate layer”. Specifically, the in-plane retardation Re of the low-Re substrate layer at a temperature of 23° C. and a measurement wavelength of 590 nm is preferably less than 100 nm, more preferably 20 nm or less, even more preferably 10 nm or less, and ideally 0 nm. For example, when the multilayer film is used as a component of an on-cell- or mid-cell-type touch panel, the substrate layer is preferably a low-Re substrate layer having a small birefringence.

Alternatively, the in-plane retardation Re of the substrate layer may be large. For example, the in-plane retardation Re of the substrate layer at a temperature of 23° C. and a measurement wavelength of 590 nm may be 100 nm or more and 300 nm or less. In the following description, the substrate layer having such a large in-plane retardation Re may be referred to as a “high-Re substrate layer”.

The specific in-plane retardation Re of a high-Re substrate layer may be set depending on a role that should be played by the high-Re substrate layer. For example, the high-Re substrate layer may have an in-plane retardation Re of ¼ wavelength. Specifically, the in-plane retardation Re of ¼ wavelength is usually 108 nm or more, and preferably 116 nm or more, and is usually 168 nm or less, and preferably 156 nm or less. As another example, the high-Re substrate layer may have an in-plane retardation Re of ½ wavelength. Specifically, the in-plane retardation Re of ½ wavelength is usually 240 nm or more, and preferably 250 nm or more, and is usually 300 nm or less, preferably 280 nm or less, and more preferably 270 nm or less. In the following description, a high-Re substrate layer having an in-plane retardation Re of ¼ wavelength may be referred to as a “λ/4 substrate layer”, and a high-Re substrate layer having an in-plane retardation Re of ½ wavelength may be referred to as a “λ/2 substrate layer”.

The birefringence Δn of the high-Re substrate layer is preferably 0.0010 or more, and more preferably 0.003 or more. The upper limit of the birefringence Δn is not particularly limited, and is usually 0.1 or less. When the birefringence Δn of the high-Re substrate layer is equal to or more than the above-described lower limit value, it is possible to obtain a thin multilayer film having desired optical performance.

The direction of slow axis of the substrate layer is optionally set depending on the intended use of the multilayer film. In particular, when the multilayer film has a long-length shape and the substrate layer is a high-Re substrate layer, the slow axis of the high-Re substrate layer is preferably present in an oblique direction relative to the lengthwise direction of the multilayer film. The oblique direction relative to the lengthwise direction refers to a direction that is neither parallel nor perpendicular to the lengthwise direction. Usually, the polarized light transmission axis of a linear polarizing film is parallel or perpendicular to the lengthwise direction. Therefore, when the direction of slow axis of the high-Re substrate layer is set in such a manner as described above, a polarizing plate can be produced by bonding together the multilayer film and the linear polarizing film by a roll-to-roll method. The range of the angle formed between the lengthwise direction of the multilayer film and the slow axis of the high-Re substrate layer may be, for example, 15°±10°, 45°±10°, or 75°±10°. In particular, the angle is preferably 15°±5°, 45°±5°, or 75°±5°, and more preferably 15°±3°, 45°±3°, or 75°±3°.

The thickness of the substrate layer is preferably 5 μm or more, and more preferably 10 μm or more, and is preferably 50 μm or less, and more preferably 30 or less. According to the findings of the present inventor, when the above-described specific material is used as a material of the substrate layer and an organic electroconductive layer is used as an electroconductive layer, the bend resistance of the multilayer film can be enhanced by adjusting the thickness of the substrate layer to a value within such a specific range.

The above-described substrate layer may be produced by, for example, a production method including the step of molding a crystallizable resin containing a crystallizable polymer into the form of film.

Examples of a method for molding a crystallizable resin to produce a substrate layer may include resin molding methods such as an injection molding method, an extrusion molding method, a press molding method, an inflation molding method, a blow molding method, a calendering molding method, a cast molding method, and a compression molding method. Among these, an extrusion molding method is preferable because thereby thickness can be easily controlled.

Preferable production conditions in the extrusion molding method are as follows. A cylinder temperature (molten resin temperature) is preferably Tm or higher, and more preferably Tm+20° C. or higher, and is preferably Tm+100° C. or lower, and more preferably Tm+50° C. or lower. A cast roll temperature is preferably Tg−50° C. or higher, and is preferably Tg+70° C. or lower, and more preferably Tg+40° C. or lower. A cooling roll temperature is preferably Tg−70° C. or higher, and more preferably Tg−50° C. or higher, and is preferably Tg+60° C. or lower, and more preferably Tg+30° C. or lower. When the crystallizable resin is molded under such conditions, it is possible to easily produce a film having a thickness of 1 to 1 mm. Herein, “Tm” represents the melting point of the crystallizable polymer, and “Tg” represents the glass transition temperature of the crystallizable polymer.

The thus produced film may be used as it is as a substrate layer or may be subjected to a stretching treatment to obtain a stretched film for use as a substrate layer. Therefore, the method for producing a substrate layer may include a step of stretching the crystallizable resin film.

The stretching method is not particularly limited, and any stretching method may be used. Examples of the stretching method may include: a uniaxial stretching method such as a method in which the film is uniaxially stretched in the lengthwise direction (longitudinal uniaxial stretching method) and a method in which the film is uniaxially stretched in the width direction (transverse uniaxial stretching method); a biaxial stretching method such as a simultaneous biaxial stretching method in which the film is stretched in the lengthwise direction while simultaneously stretched in the width direction and a successive biaxial stretching method in which the film is stretched in one of the lengthwise direction and the width direction and then stretched in the other direction; and a method in which the film is stretched in an oblique direction that is neither parallel nor perpendicular to the width direction (oblique stretching method). Among these, the method for producing a substrate layer preferably includes oblique stretching performed once or more.

Examples of the above-described longitudinal uniaxial stretching method may include a stretching method using a difference in peripheral speed between rolls.

Examples of the above-described transverse uniaxial stretching method may include a stretching method using a tenter stretching machine.

Examples of the above-described simultaneous biaxial stretching method may include a stretching method using a tenter stretching machine including a plurality of clips that are movably provided along guide rails and can fix the film, in which the film is stretched in the lengthwise direction by increasing the distance between the clips while simultaneously stretched in the width direction by utilizing the spread angle between the guide rails.

Examples of the above-described successive biaxial stretching method may include a stretching method in which the film is stretched in the lengthwise direction using a difference in peripheral speed between rolls and then stretched in the width direction by a tenter stretching machine by gripping the both ends thereof with clips.

Examples of the above-described oblique stretching method may include a stretching method in which a film is continuously stretched in its oblique direction using a tenter stretching machine capable of applying, to the film, a feeding force, a tensile force, or a take-up force which differs in speed between the left and right sides in the lengthwise direction or the width direction.

A stretching temperature is preferably Tg−30° C. or higher, and more preferably Tg−10° C. or higher, and is preferably Tg+60° C. or lower, and more preferably Tg+50° C. or lower. The “Tg” herein represents the grass transition temperature of the crystallizable polymer. When the film is stretched within such a temperature range, polymer molecules contained in the film can appropriately be oriented.

A stretching ratio may appropriately be selected depending on desired optical properties, thickness, strength, etc., and is usually more than 1 time, preferably 1.01 times or more, and more preferably 1.1 times or more, and is usually 10 times or less, and preferably 5 times or less. Herein, when stretching is performed in two or more different directions like, for example, a biaxial stretching method, a total stretching ratio expressed as a product of stretching ratios in different stretching directions is regarded as a stretching ratio. When the stretching ratio is equal to or less than the upper limit of the above-described range, it is possible to easily produce a substrate layer because the possibility of film fracture can be reduced.

By subjecting the crystallizable resin film to such stretching treatment as described above, it is possible to obtain a substrate layer having desired properties.

A film produced in such a manner as described above may be subjected to a treatment of crystallizing the crystallizable polymer contained in the film to obtain a substrate layer. Therefore, the method for producing a substrate layer may include a crystallization step in which the crystallizable polymer is crystallized. In the following description, the film to be subjected to a treatment to crystallize the crystallizable polymer is appropriately referred to as a “primary film”. The primary film may be either a film having been subjected to a stretching treatment or a film not having been subjected to a stretching treatment.

In the crystallization step, crystallization treatment is usually performed to crystallize the crystallizable polymer within a particular temperature range in a state where the primary film comprising a crystallizable resin is strained by holding at least two edges of the primary film. By performing this step, it is possible to easily produce a substrate layer containing a crystallized crystallizable polymer, and thereby a substrate layer having excellent properties described above can be easily obtained.

The thickness of the primary film may optionally be set depending on the thickness of the substrate layer, and is usually 5 μm or more, and preferably 10 μm or more, and is usually 1 mm or less, and preferably 500 μm or less.

The state where the primary film is strained refers to a state where a tension is applied to the primary film. However, the state where the primary film is strained does not include a state where the primary film is substantially stretched. The phrase “substantially stretched” means that the stretching ratio of the primary film in any direction is usually 1.1 times or more.

When the primary film is held, the primary film is held by an appropriate holder. The holder may be either one that can continuously hold the entire lengths of edges of the primary film or one that can intermittently hold the primary film at intervals. For example, the edges of the primary film may intermittently be held with holders disposed at particular intervals.

In the crystallization step, at least two edges of the primary film are held to create a state where the primary film is strained. This makes it possible to prevent deformation of the primary film caused by thermal shrinkage in an area between the held edges. In order to prevent deformation in a wide area of the primary film, it is preferable that edges including two opposed edges are held so that an area between the held edges is kept in a strained state. For example, when two opposed edges (e.g., long-side edges or short-side edges) of a primary film having a rectangular sheet piece shape are held to keep an area between the two edges in a strained state, it is possible to prevent deformation of the entire primary film having the sheet piece shape. When two edges at the width-direction ends (i.e., long-side edges) of a long length primary film are held to keep an area between the two edges in a strained state, it is possible to prevent deformation of the entire long-length primary film. By preventing deformation of the primary film in such a manner as described above, the occurrence of deformation such as wrinkling is prevented even when stress is generated in the film by thermal shrinkage. When a stretched film having been subjected to a stretching treatment is used as a primary film, deformation can more reliably be prevented by holding at least two edges orthogonal to the stretching direction (in the case of biaxial stretching, a direction in which the stretching ratio is larger).

In order to more reliably prevent deformation in the crystallization step, a larger number of edges are preferably held. Therefore, in the case of, for example, a primary film having a sheet piece shape, all the edges thereof are preferably held. More specifically, in the case of a primary film having a rectangular sheet piece shape, four edges thereof are preferably held.

It is preferable that the holder capable of holding the edges of the primary film does not come into contact with the primary film in portions other than the edges of the primary film. The use of such a holder makes it possible to obtain a substrate layer having more excellent surface smoothness.

It is also preferable that the holders can fix the relative positions thereof in the crystallization step. Since the relative positions between such holders do not alter in the crystallization step, prevention of substantial stretching of the primary film in the crystallization step can be easily achieved.

Preferred examples of the holder for, for example, a rectangular primary film may include grippers such as clips that are provided on a frame at particular intervals and can grip the edges of the primary film. Examples of the holder for, for example, holding two edges at the width-direction ends of a long-length primary film may include grippers that are provided in a tenter stretching machine and can grip the edges of the primary film.

When a long-length primary film is used, edges at the lengthwise direction ends (i.e., short-side edges) of the primary film may be held. Instead of holding the above-described edges, both sides in the lengthwise direction of an area to be subjected to a crystallization treatment in the primary film may be held. For example, holding devices may be provided on both sides of the primary film in the lengthwise direction of an area to be subjected to a crystallization treatment so that the primary film can be held in a strained state so as not to thermally shrink. Examples of such holding devices may include a combination of two rolls, and a combination of an extruder and a taking-up roll. When a tension such as a feeding tension is applied to the primary film by such a combination, it is possible to prevent thermal shrinkage of the primary film in an area subjected to a crystallization treatment. Therefore, when such a combination is used as holding devices, the primary film can be held while being conveyed in the lengthwise direction, which make is possible to efficiently produce a substrate layer.

In the crystallization step, the primary film is usually adjusted to a temperature equal to or higher than the glass transition temperature Tg of the crystallizable polymer and equal to or lower than the melting point Tm of the crystallizable polymer in a state where the primary film is strained by holding at least two edges thereof in such a manner as described above. In the primary film adjusted to such a temperature as described above, crystallization of the crystallizable polymer proceeds. Therefore, by performing the crystallization step, it is possible to obtain a film as a substrate layer containing a crystallized crystallizable polymer. At this time, the film is in a state where the film is strained so as to be prevented from deforming, and therefore crystallization is allowed to proceed without impairing the surface smoothness of the film.

As described above, the temperature range in the crystallization step may usually be set to any value within a temperature range of equal to or higher than the glass transition temperature Tg of the crystallizable polymer and equal to or lower than the melting point Tm of the crystallizable polymer. In particular, the temperature in the crystallization step is preferably set so that a high crystallization speed is achieved. The temperature of the primary film in the crystallization step is preferably Tg+30° C. or higher, and more preferably Tg+40° C. or higher, and is preferably Tm−20° C. or lower, and more preferably Tm−40° C. or lower. When the temperature in the crystallization step is equal to or lower than the upper limit of the above-described range, it is possible to prevent clouding of a substrate layer, and thereby a substrate layer suitable for a multilayer film required to be optically transparent can be obtained.

When the primary film is set to the above-described temperature, the primary film is usually heated. A heating device used at this time is preferably one capable of increasing the temperature of an atmosphere around the primary film because such a heating device does not need to come into contact with the primary film. Specific examples of such a preferred heating device may include an oven and a heating furnace.

In the crystallization step, a treatment time during which the primary film is maintained at a temperature within the above-described range is preferably 1 second or longer, and more preferably 5 seconds or longer, and is preferably 30 minutes or shorter, and more preferably 10 minutes or shorter. By allowing crystallization of the crystallizable polymer to sufficiently proceed in the crystallization step, it is possible to enhance the bend resistance of a substrate layer. When the treatment time is equal to or shorter than the upper limit of the above-described range, it is possible to prevent clouding of a substrate layer, and thereby a substrate layer suitable for a multilayer film required to be optically transparent can be obtained.

In the method for producing the substrate layer, an optional step may further be performed in combination with the above-described crystallization step. Examples of the optional step may include: a relaxation step in which a residual stress is removed by thermally shrinking the substrate layer after the crystallization step; and a surface treatment step in which the obtained substrate layer is subjected to a surface treatment.

Production of the above-described substrate layer may be performed by, for example, a method disclosed in International Publication No. 2016/067893.

[3. Barrier Layer]

The barrier layer may be an organic barrier layer comprising an organic material, an inorganic barrier layer comprising an inorganic material, or a combination of these barrier layers. Further, the barrier layer may be a layer having a single-layer structure including only one layer or a layer having a multilayer structure including two or more layers. For example, the barrier layer may be a layer having a multilayer structure in which organic barrier layers and inorganic barrier layers are alternately provided in the thickness direction.

The multilayer film preferably includes, as a barrier layer, one or more inorganic barrier layers. Therefore, the barrier layer is preferably one comprising only one inorganic barrier layer, one comprising two or more inorganic barrier layers, or a combination of an inorganic barrier layer and an organic barrier layer. When the barrier layer includes one or more inorganic barrier layers, excellent barrier performance can be exhibited. In general, there is a possibility that a resin film deforms depending on conditions for forming a barrier layer. However, in the present application, since a specific material that has been described above is used as a substrate layer, such deformation can be reduced.

Examples of the organic material that may be contained in the organic barrier layer may include resins containing a gas barrier polymer, such as polyvinyl alcohol, an ethylene-vinyl alcohol copolymer, and vinylidene chloride. As these resins, one type thereof may be solely used, and two or more types thereof may also be used in combination at any ratio.

Such an organic barrier layer may be formed by, for example, a method in which a resin solution containing a gas barrier polymer and a solvent is applied onto a support such as a substrate layer and dried. Such an organic barrier layer may be formed by, for example, a method in which a film containing monomers of a gas barrier polymer is formed on a support such as a substrate layer and the monomers are polymerized in the film.

Examples of the inorganic material that may be contained in the inorganic barrier layer may include inorganic oxides. Examples of the inorganic oxides may include metallic oxides, non-metallic oxides, and sub-metallic oxides. Specific examples thereof may include aluminum oxide, zinc oxide, antimony oxide, indium oxide, calcium oxide, cadmium oxide, silver oxide, gold oxide, chromium oxide, silicon oxide, cobalt oxide, zirconium oxide, tin oxide, titanium oxide, iron oxide, copper oxide, nickel oxide, platinum oxide, palladium oxide, bismuth oxide, magnesium oxide, manganese oxide, molybdenum oxide, vanadium oxide, and barium oxide. Among these, silicon oxide is particularly preferred. As these inorganic materials, one type thereof may be solely used, and two or more types thereof may also be used in combination at any ratio. As the inorganic material, a compounding agent may be used in combination with the above-described inorganic oxide. Examples of the compounding agent may include: elemental metals, elemental non-metals, elemental sub-metals, and hydroxides thereof; and carbon or fluorine for improving flexibility.

The inorganic barrier layer may be formed by, for example, a method in which an inorganic oxide is vapor-deposited onto a support such as a substrate layer. Examples of the vapor deposition method for use may include a vacuum deposition method, a vacuum sputtering method, an ion plating method, and a CVD method. Among these, a CVD method is preferable. The formation of a barrier layer by a CVD method may be performed by, for example, a method disclosed in International Publication No. 2016/067893.

The total thickness of the barrier layer is preferably 1 nm or more, more preferably 5 nm or more, and particularly preferably 10 nm or more, and is preferably 30 or less, more preferably 10 μm or less, and particularly preferably 5 μm or less. When the thickness of the barrier layer is equal to or more than the lower limit value of the above-described range, it is possible to enhance the gas barrier performance of the barrier layer. When the thickness of the barrier layer is equal to or lower than the upper limit value of the above-described range, it is possible to reduce the thickness of the barrier layer.

The thickness of each barrier layer is preferably 1 nm to 1000 nm, more preferably 10 nm to 1000 nm, and particularly preferably 10 nm to 200 nm. When the thickness of each barrier layer is equal to or more than the lower limit value of the above-described range, it is possible to prevent the barrier layer from being distributed as islands, thereby improving a water vapor barrier property. When the thickness of each barrier layer is equal to or lower than the upper limit value of the above-described range, cracking caused by bending stress can be prevented, which also makes it possible to improve a water vapor barrier property. In particular, when the thickness of an organic barrier layer is equal to or more than the lower limit value of the above-described range, thickness uniformity can be easily enhanced, which makes it easy to improve barrier properties. When the thickness of an organic barrier layer is equal to or lower than the upper limit value of the above-described range, it is possible to prevent the occurrence of cracking in the organic barrier layer due to an external force generated by, for example, bending, thereby preventing a reduction in barrier properties.

[4. Electroconductive Layer]

The electroconductive layer may be an organic electroconductive layer containing an organic electroconductive material, an inorganic electroconductive layer containing an inorganic electroconductive material, or an electroconductive layer containing a combination of these electroconductive layers. Further, the electroconductive layer may be a layer having a single-layer structure including only one layer or a layer having a multilayer structure including two or more layers.

The multilayer film may include, as an electroconductive layer, one or more organic electroconductive layers. As the organic electroconductive material contained in the organic electroconductive layer, an organic material having both transparency and electroconductivity may appropriately be used. Preferred examples of the organic electroconductive material may include polythiophene, polypyrrole, polyaniline, and polyquinoxaline. Among these, polythiophene and polyaniline are preferable for their excellent electroconductivity and optical properties, and polythiophene is particularly preferable.

Polythiophene is a polymer containing a polymerization unit having a structure obtained by polymerization of thiophene or a derivative thereof. Hereinafter, the polymerization unit having a structure obtained by polymerization of thiophene or a derivative thereof may be referred to as a “thiophene unit”. Examples of the derivative of thiophene may include a derivative having substituents at the 3-position and 4-position of a thiophene ring. More specific examples of the derivative of thiophene may include 3,4-ethylenedioxythiophene. A polymer of such ethylenedioxythiophene, that is, polyethylenedioxythiophene is particularly preferably used.

Typical examples of the aspect of polymerization of thiophene or a derivative thereof to obtain polythiophene may include one in which a thiophene ring is bonded to other rings at its 2-position and 5-position. More specific examples of the aspect of polymerization may include one in which the thiophene ring of ethylenedioxythiophene is bonded to other rings at its 2-position and 5-position.

Polythiophene may contain a polymerization unit other than the thiophene unit.

The molecular weight of polythiophene is not particularly limited, and polythiophene having a desired molecular weight for achieving desired electroconductivity may be appropriately selected.

Polythiophene is preferably used in combination with a polystyrenesulfonic acid compound. The polystyrenesulfonic acid compound is a polymer containing a polymerization unit having a structure obtained by polymerization of styrenesulfonic acid or a derivative thereof. Hereinafter, the polymerization unit having a structure obtained by polymerization of styrenesulfonic acid or a derivative thereof may be referred to as a “styrenesulfonic acid unit”.

The polystyrenesulfonic acid compound may have a polymerization unit other than the styrenesulfonic acid unit.

The content of the electroconductive polymer in the organic electroconductive layer and the contents of polythiophene and polystyrenesulfonic acid compound in the electroconductive polymer may appropriately be adjusted to achieve desired properties such as electroconductivity. Polythiophene or a mixture of polythiophene and the polystyrenesulfonic acid compound to be used may be a commercially-available product. Examples of the commercially-available product may include “Clevios (registered trademark) PH500, PH510, PH1000” manufactured by Heraeus and “Orgacon S-300” manufactured by Agfa-Gevaert Japan, Ltd.

The multilayer film may include, as an electroconductive layer, one or more inorganic electroconductive layers. Examples of the inorganic electroconductive material contained in the inorganic electroconductive layer may include: metals such as Ag and Cu; and ITO (indium tin oxide), IZO (indium zinc oxide), ZnO (zinc oxide), IWO (indium tungsten oxide), ITiO (indium titanium oxide), AZO (aluminum zinc oxide), GZO (gallium zinc oxide), XZO (zinc-based special oxide), and IGZO (indium gallium zinc oxide). For example, metallic nanowires may be used as an inorganic electroconductive material. Among these, at least one selected from the group consisting of Ag, Cu, ITO, and metallic nanowires is preferably used as an inorganic electroconductive material.

The method for forming the electroconductive layer is not limited. The electroconductive layer may be formed by, for example, applying a composition containing an electroconductive material and another optional component such as a solvent onto a support such as a substrate layer to form a layer of the composition and drying the layer of the composition. Alternatively, the electroconductive layer may be formed by, for example, forming a film of an electroconductive material on the surface of a support such as a substrate layer by a film formation method such as a vapor deposition method, a sputtering method, an ion plating method, an ion beam assisted deposition method, an arc-discharge plasma deposition method, a thermal CVD method, a plasma CVD method, a plating method, or a combination of two or more of them.

The surface resistivity of the electroconductive layer may appropriately be selected depending on the intended use, and is usually 1000 Ω/sq. or less, preferably 500 Ω/sq. or less, and more preferably 100 Ω/sq. or less. The lower limit of the surface resistivity is not particularly limited, and may be, for example, 0.1 Ω/sq. or more. The resistivity may be measured using a resistivity meter (e.g., “Loresta-GX MCP-T700” manufactured by Mitsubishi Chemical Analytech Co.).

The number of electroconductive layers included in the multilayer film may be one or two or more. For example, the multilayer film may include, as electroconductive layers, a first electroconductive layer and a second electroconductive layer formed of a material different from that of the first electroconductive layer. Further, for example, the multilayer film may include, as electroconductive layers, a first electroconductive layer and a second electroconductive layer insulated from the first electroconductive layer. For example, an electroconductive film provided in a touch panel may be formed in such a manner that an electroconductive layer X for identifying a position in a certain coordinate direction X and an electroconductive layer Y for identifying a position in a coordinate direction Y not parallel to the coordinate direction X are insulated from each other and formed in a matrix as a whole in order to identify a position a user touches on the touch panel. Therefore, a first electroconductive layer and a second electroconductive layer may be provided as the electroconductive layer X and the second electroconductive layer Y.

The thickness of the electroconductive layer is preferably 10 nm or more, more preferably 30 nm or more, and particularly preferably 50 nm or more, and is preferably 3000 nm or less, more preferably 1000 nm or less, even more preferably 250 nm or less, and particularly preferably 220 nm or less. When the thickness of the electroconductive layer is larger, the surface resistivity can generally be made lower. On the other hand, when the thickness of the electroconductive layer is equal to or less than the above-described upper limit, excellent bend resistance can be achieved.

[5. Optional Layer]

The multilayer film may further include an optional layer in combination with the above-described substrate layer, barrier layer, and electroconductive layer.

The multilayer film may include, for example, a ¼ wave film layer having an in-plane retardation Re of ¼ wavelength. In particular, the multilayer film preferably includes a ¼ wave film layer in combination with a low-Re substrate layer. When the multilayer film including a ¼ wave film layer is bonded to a linear polarizing film, a polarizing plate having an elliptical polarization function can easily be produced. Such a ¼ wave film layer can be produced as a stretched film layer by, for example, stretching a thermoplastic resin film so that a desired in-plane retardation Re is generated.

The direction of slow axis of the ¼ wave film layer is optionally set depending on the intended use of the multilayer film. In particular, when the multilayer film has a long-length shape, the slow axis of the ¼ wave film layer is preferably present in an oblique direction relative to the lengthwise direction of the multilayer film. Usually, when the multilayer film has a long-length shape, the ¼ wave film layer also has a long-length shape. Further, the polarized light transmission axis of a linear polarizing film is usually parallel or perpendicular to the lengthwise direction. Therefore, by setting the direction of slow axis of the ¼ wave film layer in such a manner as described above, the multilayer film can be bonded to a linear polarizing film by a roll-to-roll method to produce a polarizing plate. The range of an angle formed between the lengthwise direction of the multilayer film and the slow axis of the ¼ wave film layer may be, for example, 45°±10°. In particular, the angle is preferably 45°±5°, and more preferably 45°±3°.

The multilayer film may include, for example, an adhesive layer or tackiness layer for effecting adhesion or sticking of layers included in the multilayer film.

[6. Properties of Multilayer Film]

As the multilayer film includes the above-described substrate layer, barrier layer, and electroconductive layer, the multilayer film can have excellent solvent resistance. More specifically, the multilayer film is less likely to fracture, crack, whiten, discolor, swell or deform (e.g., wave) even when immersed in cyclohexane, normal hexane, methyl ethyl ketone, chloroform, or isopropanol. Therefore, the multilayer film is less likely to deteriorate due to a solvent contained in an adhesive or the like when an optical film such as a polarizing plate is produced using the multilayer film, and therefore the optical film can be stably produced. The solvent resistance of the multilayer film may be measured by a method that will be described in the example section.

The multilayer film can have excellent grease resistance. More specifically, the multilayer film is less likely to fracture, crack, whiten, discolor, swell, or deform (e.g., wave) even when immersed in oleic acid or coming into contact with Vaseline. Therefore, the multilayer film is less likely to deteriorate even when sebum from hands and the like adheres to the multilayer film during handling, and is therefore excellent in handleability. The grease resistance of the multilayer film may be measured by a method that will be described in the example section.

Further, the multilayer film usually has excellent chemical resistance. More specifically, the multilayer film is usually less likely to fracture, crack, whiten, discolor, swell, or deform (e.g., wave) even when immersed in 35% hydrochloric acid, 30% sulfuric acid, and a 30% aqueous sodium hydroxide solution. The chemical resistance of the substrate layer may be measured by a method that will be described in the example section.

The multilayer film preferably has a low water vapor transmission rate. More specifically, the water vapor transmission rate is preferably 0.01 g/(m²·day) or less, more preferably 0.005 g/(m²·day) or less, and even more preferably 0.003 g/(m²·day) or less. The lower limit of the water vapor transmission rate is not particularly limited, and is ideally zero g/(m²·day). When the multilayer film has a low water vapor transmission rate, it is possible to effectively prevent deterioration of a layer such as a light-emitting layer in an organic EL display device, thereby preventing the generation of dark spots in the display device. Such a low water vapor transmission rate can be achieved by appropriately selecting the material of a layer constituting the multilayer film, such as a barrier layer. The water vapor transmission rate may be measured in accordance with JIS K 7129 B-1992 using a water vapor transmission rate meter (trade name “PERMATRAN-W” manufactured by MOCON Corporation) under conditions of a temperature of 40° C. and 90% RH.

The electroconductive layer of the multilayer film is preferably excellent in film formation suitability. More specifically, it is preferable that the multilayer film has a film surface not deformed by, for example, wrinkling or waving while having an electroconductive layer. When the electroconductive layer has such excellent film formation suitability, it is possible to prevent the occurrence of a defect (e.g., poor bonding with a linear polarizing film) in the process of producing a product, such as a polarizing plate, using the multilayer film.

The electroconductive layer is preferably less likely to have a large resistance value even after the multilayer film is folded. For example, the change rate ΔR of the resistance value is preferably 50% or less, more preferably 40% or less, and particularly preferably 30% or less even after the multilayer film is subjected to the above-described tension-free U-shape folding test for planar objects until the number of folding cycles reaches 200,000 cycles. The change rate ΔR of the resistance value is herein expressed by the formula ΔR={R(1)−R(0)}/R(0). Further, R(0) [Ω/sq.] represents the resistance value of the electroconductive layer before test, and R(1) [Ω/sq.] represents the resistance value of the electroconductive layer after test.

The in-plane retardation Re of the multilayer film at a temperature of 23° C. and a measurement wavelength of 590 nm is preferably 140 nm or more, and more preferably 145 nm or more, and is preferably 155 nm or less, and more preferably 150 nm or less. The in-plane retardation Re of the multilayer film at a temperature of 23° C. and a measurement wavelength of 450 nm is preferably 108 nm or more, and more preferably 110 nm or more, and is preferably 115 nm or less, and more preferably 113 nm or less. The in-plane retardation Re of the multilayer film at a temperature of 23° C. and a measurement wavelength of 650 nm is preferably 158 nm or more, and more preferably 160 nm or more, and is preferably 168 nm or less, and more preferably 165 nm or less. When the multilayer film has such an in-plane retardation Re, the multilayer film can satisfactorily perform its function such as antireflection in an organic EL display device.

[7. Method for Producing Multilayer Film]

The method for producing the multilayer film is not particularly limited.

For example, the multilayer film may be produced by forming, on the surface of a substrate layer, a barrier layer and an electroconductive layer by the above-described formation method.

Alternatively, the multilayer film may be produced by bonding together an intermediate film obtained by forming a barrier layer on the surface of a substrate layer and another intermediate film obtained by forming an electroconductive layer on the surface of another substrate layer with, if necessary, an adhesive or a tackiness agent.

[8. Uses of Multilayer Film]

The multilayer film according to the present invention is a multilayer film for an organic EL display device. More specifically, the multilayer film may be used for various purposes for an organic EL display device by making use of its barrier function, electroconductive function, and optical properties. The multilayer film is preferably used as, for example, a polarizing plate or an antireflection film that will be described later.

[9. Polarizing Plate]

The polarizing plate according to the present invention includes the multilayer film according to the present invention and a linear polarizing film.

The linear polarizing film to be used may be a known polarizing film used in a device such as an organic EL display device, a liquid crystal display device, or another optical device. Examples of the linear polarizing film may include one obtained by effecting adsorption of iodine or a dichroic dye to a polyvinyl alcohol film and then uniaxially stretching the film in a boric acid bath. Another example of the linear polarizing film may be one obtained by effecting adsorption of iodine or a dichroic dye to a polyvinyl alcohol film, stretching the film, and further modifying some of polyvinyl alcohol units in molecular chains into polyvinylene units. Still another examples of the linear polarizing film may be a polarizing film having the function of separating polarized light into reflected light and transmitted light, such as a grid polarizer, a multilayer polarizer, or a cholesteric liquid crystal polarizer. Among these, linear polarizing films containing polyvinyl alcohol are preferable. The linear polarizing film to be used may be a commercially-available product (e.g., trade names “HLC2-5618S”, “LLC2-9218S”, or “HLC2-2518” manufactured by SANRITZ CORPORATION, trade names “TEG1465DU”, “SEG1423DU”, or “SEG5425DU” manufactured by Nitto Denko Corporation).

When natural light enters the linear polarizing film, only one polarized light passes through the liner polarizing film. The polarization degree of the linear polarizing film is not particularly limited, and is preferably 98% or more, and more preferably 99% or more. The average thickness of the linear polarizing film is preferably 5 μm to 80 μm.

In the polarizing plate, the multilayer film can function as a protective layer for the linear polarizing film. Further, when the multilayer film has an appropriate in-plane retardation Re, the multilayer film can function as a wave plate, so that the polarizing plate can exhibit an elliptical polarization function. The elliptical polarization function of the polarizing plate herein refers to the function of allowing non-polarized light incident on the polarizing plate to pass through as elliptically polarized light. The elliptically polarized light includes circularly polarized light. For example, when the multilayer film has an in-plane retardation Re of ¼ wavelength, the polarizing plate can function as a circular polarizing plate that allows non-polarized light incident on the polarizing plate to pass through as circularly polarized light.

The polarizing plate preferably has a long-length shape. In this case, the polarized light transmission axis of the linear polarizing film is preferably parallel to the lengthwise direction of the polarizing plate. Further, when the multilayer film included in such a long-length polarizing plate includes a λ/2 substrate layer or a λ/4 substrate layer, the slow axis of the λ/2 substrate layer or the λ/4 substrate layer is preferably present in an oblique direction relative to the lengthwise direction of the polarizing plate. Such a polarizing plate can easily be produced by a roll-to-roll method.

The polarizing plate is preferably produced by, for example, bonding a long-length multilayer film and a long-length linear polarizing film by a roll-to-roll process so that their lengthwise directions are parallel to each other. The bonding by the roll-to-roll process refers to bonding performed in such a manner wherein a film is unwound from a roll of a long-length film, the unwound film is conveyed, a step of bonding the film with another film on a conveyance line is performed, and the obtained bonded product is further wound into a roll. For example, when a linear polarizing film and a multilayer film are bonded together, the bonding by the roll-to-roll process may be performed in the following manner: a multilayer film is unwound from a roll of a long-length multilayer film, the unwound multilayer film is conveyed, a step of bonding the film with a linear polarizing film on a conveyance line is performed, and the obtained bonded product is wound into a roll. In this case, the linear polarizing film may also be unwound from a roll to be supplied to the step of bonding. The linear polarizing film to be bonded to the multilayer film may be one obtained by previously bonding with a polarizer protection film to have a multilayer structure.

In the polarizing plate, another polarizer protection film is preferably bonded to the surface of the linear polarizing film to which the multilayer film is not bonded. Both the multilayer film and the polarizer protection film preferably have a rigidity of 300 kPa·m or less and a bendability of 10 mm or more and 50 mm or less. The rigidity is herein calculated as a product of the tensile elastic modulus (Pa) of the film and the thickness (m) of the film. The difference in rigidity between the protective layers provided on both surfaces of the linear polarizing film (i.e., the multilayer film provided on one of the surfaces of the linear polarizing film and the polarizer protection film provided on the opposite side) is more preferably 20 kPa·m to 200 kPa·m.

Examples of the polarizer protection film may include ZEONOR film manufactured by ZEON Corporation, TAC film for LCD polarizers manufactured by KONICA MINOLTA, INC., and FUJITAC manufactured by FUJIFILM Corporation. The polarizer protection film may be either a single-layer film or a multilayer film. When the multilayer film according to the present invention has bendability, it is possible to obtain a flexible polarizing plate including protective layers on both surfaces of a polarizing film, and the use of such a polarizing plate makes it possible to obtain an organic EL display device having a curved surface. Such an organic EL display device having a curved surface is excellent in decorativeness and design. In particular, when such an organic EL display device is used for a portable device such as a smartphone, the portable device can tightly be held in the hand.

Hereinbelow, preferred embodiments of the polarizing plate will be described with reference to drawings. All the polarizing plates that will be described below as embodiments are those having an elliptical polarization function.

[9.1. Polarizing Plate as First Embodiment]

First to fifth embodiments that will be described below each use, as a substrate layer, a low-Re substrate layer not having large optical anisotropy.

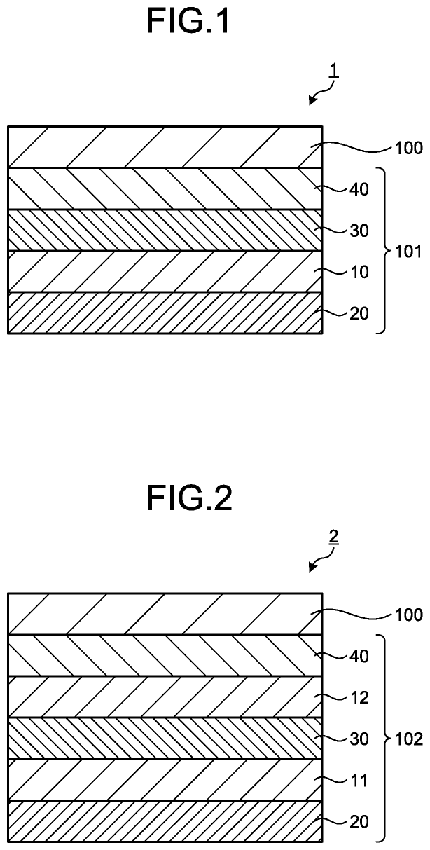

FIG. 1 is a cross-sectional view schematically illustrating a polarizing plate 1 as a first embodiment of the present invention.

As illustrated in FIG. 1, the polarizing plate 1 as the first embodiment of the present invention includes: a linear polarizing film 100; and a multilayer film 101 including a low-Re substrate layer 10 as a substrate layer, a barrier layer 20, an electroconductive layer 30, and a ¼ wave film layer 40. The multilayer film 101 includes the barrier layer 20, the low-Re substrate layer 10, the electroconductive layer 30, and the ¼ wave film layer 40 in this order.

The surface of the multilayer film 101 on the ¼ wave film layer 40 side is bonded to the linear polarizing film 100. In this case, the bonding angle between the linear polarizing film 100 and the multilayer film 101 is set so that the angle formed between the polarized light transmission axis of the linear polarizing film 100 and the slow axis of the ¼ wave film layer 40 is 35° or more and 55° or less. The multilayer film 101 functions as a ¼ wave plate having an in-plane retardation Re of ¼ wavelength, and thereby the polarizing plate 1 can exhibit an elliptical polarization function.

Such a polarizing plate 1 can be provided as an antireflection film in an organic EL display device. In this case, the polarizing plate 1 is usually provided so that the linear polarizing film 100, the ¼ wave film layer 40, the electroconductive layer 30, the low-Re substrate layer 10, and the barrier layer 20 are disposed in this order from the viewing side.

In the polarizing plate 1, at least one of the barrier layer 20 and the electroconductive layer 30 is provided so as to be in direct contact with the low-Re substrate layer 10, and preferably, both the barrier layer 20 and the electroconductive layer 30 are provided so as to be in direct contact with the low-Re substrate layer 10.

[9.2. Polarizing Plate as Second Embodiment]

FIG. 2 is a cross-sectional view schematically illustrating a polarizing plate 2 as a second embodiment of the present invention.

As illustrated in FIG. 2, the polarizing plate 2 as the second embodiment of the present invention uses a multilayer film 102 including, as substrate layers, a low-Re substrate layer 11 and a low-Re substrate layer 12. More specifically, the multilayer film 102 includes a barrier layer 20, the low-Re substrate layer 11, an electroconductive layer 30, the low-Re substrate layer 12, and a ¼ wave film layer 40 in this order.

The surface of the multilayer film 102 on the ¼ wave film layer 40 side is bonded to the linear polarizing film 100. In this case, the bonding angle between the linear polarizing film 100 and the multilayer film 102 is set so that, as in the case of the first embodiment, the angle formed between the polarized light transmission axis of the linear polarizing film 100 and the slow axis of the ¼ wave film layer 40 falls within the particular range. The multilayer film 102 functions as a ¼ wave plate having an in-plane retardation Re of ¼ wavelength, and thereby the polarizing plate 2 can exhibit an elliptical polarization function.

Such a polarizing plate 2 can be provided as an antireflection film in an organic EL display device. In this case, the polarizing plate 2 is usually provided so that the linear polarizing film 100, the ¼ wave film layer 40, the low-Re substrate layer 12, the electroconductive layer 30, the low Re-substrate layer 11, and the barrier layer 20 are disposed in this order from the viewing side.

In the polarizing plate 2, at least one of the barrier layer 20 and the electroconductive layer 30 is provided so as to be in direct contact with at least one of the low-Re substrate layer 11 and the low-Re substrate layer 12, and preferably, both the barrier layer 20 and the electroconductive layer 30 are provided so as to be in direct contact with at least one of the low-Re substrate layer 11 and the low-Re substrate layer 12. For example, the barrier layer 20 may be in direct contact with the low-Re substrate layer 11, and the electroconductive layer 30 may be in direct contact with the low-Re substrate layer 12. As another example, both the barrier layer 20 and the electroconductive layer 30 may be in direct contact with the low-Re substrate layer 11.

[9.3. Polarizing Plate as Third Embodiment]

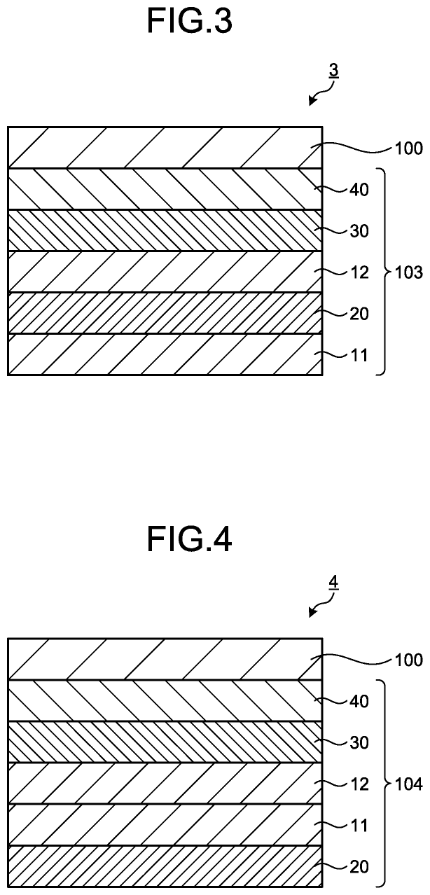

FIG. 3 is a cross-sectional view schematically illustrating a polarizing plate 3 as a third embodiment of the present invention.

As illustrated in FIG. 3, the polarizing plate 3 as a third embodiment of the present invention uses a multilayer film 103 different from that used in the second embodiment in the order of layers. More specifically, the multilayer film 103 includes a low-Re substrate layer 11, a barrier layer 20, a low-Re substrate layer 12, an electroconductive layer 30, and a ¼ wave film layer 40 in this order.

The surface of the multilayer film 103 on the ¼ wave film layer 40 side is bonded to the linear polarizing film 100. In this case, the bonding angle between the linear polarizing film 100 and the multilayer film 103 is set so that, as in the case of the first embodiment, the angle formed between the polarized light transmission axis of the linear polarizing film 100 and the slow axis of the ¼ wave film layer 40 falls within the particular range. The multilayer film 103 functions as a ¼ wave plate having an in-plane retardation Re of ¼ wavelength, and thereby the polarizing plate 3 can exhibit an elliptical polarization function.

Such a polarizing plate 3 can be provided as an antireflection film in an organic EL display device. In this case, the polarizing plate 3 is usually provided so that the linear polarizing film 100, the ¼ wave film layer 40, the electroconductive layer 30, the low-Re substrate layer 12, the barrier layer 20, and the low-Re substrate layer 11 are disposed in this order from the viewing side.

In the polarizing plate 3, at least one of the barrier layer 20 and the electroconductive layer 30 is provided so as to be in direct contact with at least one of the low-Re substrate layer 11 and the low-Re substrate layer 12, and preferably, both the barrier layer 20 and the electroconductive layer 30 are provided so as to be in direct contact with at least one of the low-Re substrate layer 11 and the low-Re substrate layer 12. For example, the barrier layer 20 may be in direct contact with the low-Re substrate layer 11, and the electroconductive layer 30 may be in direct contact with the low-Re substrate layer 12. As another example, both the barrier layer 20 and the electroconductive layer 30 may be in direct contact with the low-Re substrate layer 12.

[9.4. Polarizing Plate as Fourth Embodiment]

FIG. 4 is a cross-sectional view schematically illustrating a polarizing plate 4 as a fourth embodiment of the present invention.

As illustrated in FIG. 4, the polarizing plate 4 as the fourth embodiment of the present invention uses a multilayer film 104 different from those of the second embodiment and of the third embodiment in the order of layers. Specifically, the multilayer film 104 includes a barrier layer 20, a low-Re substrate layer 11, a low-Re substrate layer 12, an electroconductive layer 30, and a ¼ wave film layer 40 in this order.

The surface of the multilayer film 104 on the ¼ wave film layer 40 side is bonded to the linear polarizing film 100. In this case, the bonding angle between the linear polarizing film 100 and the multilayer film 104 is set so that, as in the case of the first embodiment, the angle formed between the polarized light transmission axis of the linear polarizing film 100 and the slow axis of the ¼ wave film layer 40 falls within the particular range. The multilayer film 104 functions as a ¼ wave plate having an in-plane retardation Re of ¼ wavelength, and thereby the polarizing plate 4 can exhibit an elliptical polarizing function.

Such a polarizing plate 4 can be provided as an antireflection film in an organic EL display device. In this case, the polarizing plate 4 is usually provided so that the linear polarizing film 100, the ¼ wave film layer 40, the electroconductive layer 30, the low-Re substrate layer 12, the low-Re substrate layer 11, and the barrier layer 20 are disposed in this order from the viewing side.

In the polarizing plate 4, at least one of the barrier layer 20 and the electroconductive layer 30 is provided so as to be in direct contact with at least one of the low-Re substrate layer 11 and the low-Re substrate layer 12, and preferably, both the barrier layer 20 and the electroconductive layer 30 are provided so as to be in direct contact with at least one of the low-Re substrate layer 11 and the low-Re substrate layer 12. For example, the barrier layer 20 may be in direct contact with the low-Re substrate layer 11 and the electroconductive layer 30 may be in direct contact with the low-Re substrate layer 12.

[9.5. Polarizing Plate as Fifth Embodiment]

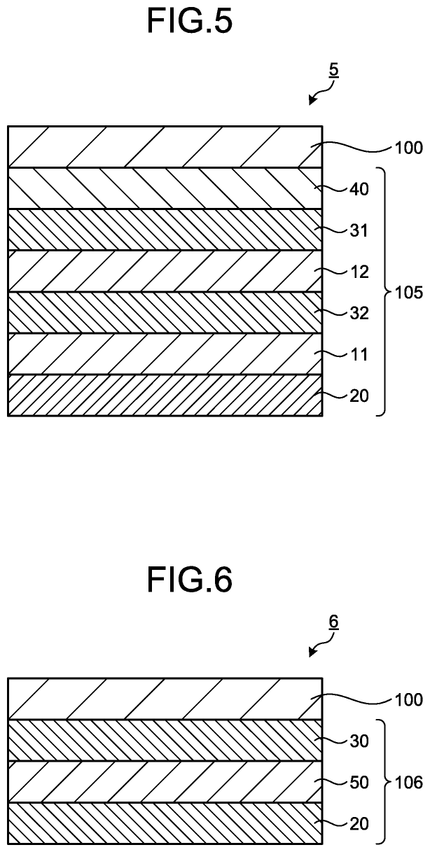

FIG. 5 is a cross-sectional view schematically illustrating a polarizing plate 5 as a fifth embodiment of the present invention.

As illustrated in FIG. 5, the polarizing plate 5 as the fifth embodiment of the present invention uses a multilayer film 105 including, as electroconductive layers, a first electroconductive layer 31 and a second electroconductive layer 32. Specifically, the multilayer film 105 includes a barrier layer 20, a low-Re substrate layer 11, a second electroconductive layer 32, a low-Re substrate layer 12, a first electroconductive layer 31, and a ¼ wave film layer 40 in this order.

The surface of the multilayer film 105 on the ¼ wave film layer 40 side is bonded to the linear polarizing film 100. In this case, the bonding angle between the linear polarizing film 100 and the multilayer film 105 is set so that, as in the case of the first embodiment, the angle formed between the polarized light transmission axis of the linear polarizing film 100 and the slow axis of the ¼ wave film layer 40 falls within the particular range. The multilayer film 105 functions as a ¼ wave plate having an in-plane retardation Re of ¼ wavelength, and thereby the polarizing plate 5 can exhibit an elliptical polarization function.

Such a polarizing plate 5 can be provided as an antireflection film in an organic EL display device. In this case, the polarizing plate 5 is usually provided in such a manner that the linear polarizing film 100, the ¼ wave film layer 40, the first electroconductive layer 31, the low-Re substrate layer 12, the second electroconductive layer 32, the low-Re substrate layer 11, and the barrier layer 20 are disposed in this order from the viewing side.

In the polarizing plate 5, at least one of the barrier layer 20 and “the first electroconductive layer 31 and the second electroconductive layer 32” is provided so as to be in direct contact with at least one of the low-Re substrate layer 11 and the low-Re substrate layer 12. Therefore, the barrier layer 20 may be in direct contact with at least one of the low-Re substrate layer 11 and the low-Re substrate layer 12. The first electroconductive layer 31 and the second electroconductive layer 32 may be in direct contact with at least one of the low-Re substrate layer 11 and the low-Re substrate layer 12. All of the barrier layer 20, the first electroconductive layer 31, and the second electroconductive layer 32 may be in direct contact with at least one of the low-Re substrate layer 11 and the low-Re substrate layer 12. Preferably, both the barrier layer 20 and “the first electroconductive layer 31 and the second electroconductive layer 32” are provided so as to be in direct contact with at least one of the low-Re substrate layer 11 and the low-Re substrate layer 12. For example, the barrier layer 20 and the second electroconductive layer 32 may be in direct contact with the low-Re substrate layer 11, and the first electroconductive layer 31 may be in direct contact with the low-Re substrate layer 12. As another example, the barrier layer 20 may be in direct contact with the low-Re substrate layer 11, and the first electroconductive layer 31 and the second electroconductive layer 32 may be in direct contact with the low-Re substrate layer 12.

[9.6. Polarizing Plate as Sixth Embodiment]

Subsequently, in a sixth embodiment to a tenth embodiment, embodiments in which a high-Re substrate layer having a large optical anisotropy is used as the substrate layer while a ¼ wave film layer is not included will be described.

FIG. 6 is a cross-sectional view schematically illustrating a polarizing plate 6 as a sixth embodiment of the present invention.

As illustrated in FIG. 6, the polarizing plate 6 as the sixth embodiment of the present invention uses a multilayer film 106 including a λ/4 substrate layer 50 having an in-plane retardation Re of ¼ wavelength as a substrate layer. Specifically, the multilayer film 106 includes the barrier layer 20, the λ/4 substrate layer 50, and the electroconductive layer 30 in this order.

The surface of the multilayer film 106 on the electroconductive layer 30 side is bonded to the linear polarizing film 100. In this case, the bonding angle between the linear polarizing film 100 and the multilayer film 106 is set so that the angle formed between the polarized light transmission axis of the linear polarizing film 100 and the slow axis of the λ/4 substrate layer 50 falls within the range of usually 35° or more and 55° or less, preferably 40° or more and 50° or less, and more preferably 42° or more and 48° or less. The multilayer film 106 functions as a ¼ wave plate having an in-plane retardation Re of ¼ wavelength, and thereby the polarizing plate 6 can exhibit an elliptical polarizing function.

Such a polarizing plate 6 can be provided as an antireflection film in an organic EL display device. In this case, the polarizing plate 6 is usually provided so that the linear polarizing film 100, the electroconductive layer 30, the λ/4 substrate layer 50, and the barrier layer 20 are disposed in this order from the viewing side.

In this polarizing plate 6, at least one of the barrier layer 20 and the electroconductive layer 30 is provided so as to be in direct contact with the λ/4 substrate layer 50, and preferably, both the barrier layer 20 and the electroconductive layer 30 are provided so as to be in direct contact with the λ/4 substrate layer 50.

[9.7. Polarizing Plate as Seventh Embodiment]

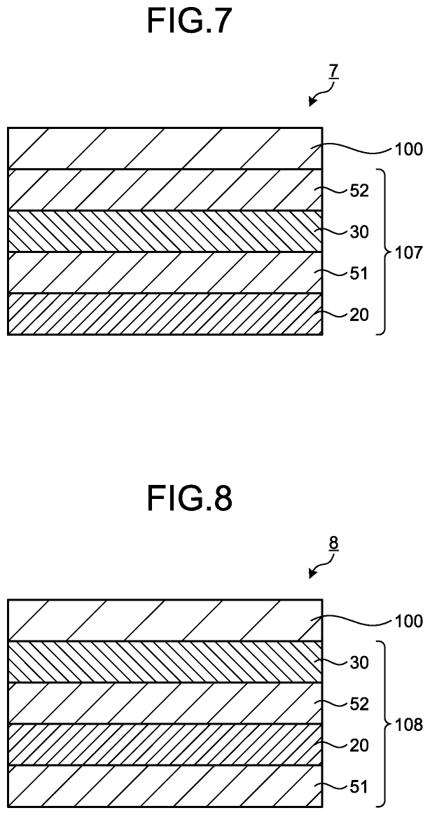

FIG. 7 is a cross-sectional view schematically illustrating a polarizing plate 7 as a seventh embodiment of the present invention.

As illustrated in FIG. 7, the polarizing plate 7 as the seventh embodiment of the present invention uses a multilayer film 107 including a λ/4 substrate layer 51 having an in-plane retardation Re of ¼ wavelength and a λ/2 substrate layer 52 having an in-plane retardation Re of ½ wavelength as substrate layers. Specifically, the multilayer film 107 includes a barrier layer 20, a λ/4 substrate layer 51, an electroconductive layer 30, and a λ/2 substrate layer 52 in this order.

In the multilayer film 107, the angle formed between the slow axis of the λ/2 substrate layer 52 and the slow axis of the λ/4 substrate layer 51 is usually 55° or more and 65° or less, and preferably 57° or more and 63° or less. Thus, the combination of the λ/4 substrate layer 51 and the λ/2 substrate layer 52 makes the multilayer film 107 a broadband ¼ wave plate capable of functioning as a ¼ wave plate in a wide wavelength range.

The surface of the multilayer film 107 on the λ/2 substrate layer 52 side is bonded to the linear polarizing film 100. In this case, the bonding angle between the linear polarizing film 100 and the multilayer film 107 is set so that the angle formed between the polarized light transmission axis of the linear polarizing film 100 and the slow axis of the λ/2 substrate layer 52 falls within a particular range. Specifically, the angle formed between the polarized light transmission axis of the linear polarizing film 100 and the slow axis of the λ/2 substrate layer 52 is approximately 15° or approximately 75°. Herein, the term “approximately 15°” is 15° or an angle close thereto, and is usually 10° or more and 20° or less, preferably 11° or more and 19° or less, and more preferably 12° or more and 18° or less. The term “approximately 75°” is 75° or an angle close thereto, and is usually 70° or more and 80° or less, preferably 71° or more and 79° or less, and more preferably 72° or more and 78° or less. The multilayer film 107 functions as a broadband ¼ wave plate, and thereby the polarizing plate 7 can exhibit an elliptical polarization function in a wide wavelength range.

Such a polarizing plate 7 can be provided as an antireflection film in an organic EL display device. In this case, the polarizing plate 7 is usually provided so that the linear polarizing film 100, the λ/2 substrate layer 52, the electroconductive layer 30, the λ/4 substrate layer 51, and the barrier layer 20 are disposed in this order from the viewing side.

In the polarizing plate 7, at least one of the barrier layer 20 and the electroconductive layer 30 is provided so as to be in direct contact with at least one of the λ/4 substrate layer 51 and the λ/2 substrate layer 52, and preferably, both the barrier layer 20 and the electroconductive layer 30 are provided so as to be in direct contact with at least one of the λ/4 substrate layer 51 and the λ/2 substrate layer 52. For example, the barrier layer 20 may be in direct contact with the λ/4 substrate layer 51, and the electroconductive layer 30 may be in direct contact with the λ/2 substrate layer 52. As another example, both the barrier layer 20 and the electroconductive layer 30 may be in direct contact with the λ/4 substrate layer 51.

[9.8. Polarizing Plate as Eighth Embodiment]

FIG. 8 is a cross-sectional view schematically illustrating a polarizing plate 8 as an eighth embodiment of the present invention.

As illustrated in FIG. 8, the polarizing plate 8 as the eighth embodiment of the present invention uses a multilayer film 108 different from that of the seventh embodiment in the order of layers. Specifically, the multilayer film 108 includes a λ/4 substrate layer 51, a barrier layer 20, a λ/2 substrate layer 52, and an electroconductive layer 30 in this order.

In the multilayer film 108, the angle formed between the slow axis of the λ/2 substrate layer 52 and the slow axis of the λ/4 substrate layer 51 is set to fall within the same particular range as that in the seventh embodiment. Thus, the combination of the λ/4 substrate layer 51 and the λ/2 substrate layer 52 makes the multilayer film 108 a broadband ¼ wave plate.

The surface of the multilayer film 108 on the electroconductive layer 30 side is bonded to the linear polarizing film 100. In this case, the bonding angle between the linear polarizing film 100 and the multilayer film 108 is set so that the angle formed between the polarized light transmission axis of the linear polarizing film 100 and the slow axis of the λ/2 substrate layer 52 falls within the same particular range as that in the seventh embodiment. The multilayer film 108 functions as a broadband ¼ wave plate, and thereby the polarizing plate 8 can exhibit an elliptical polarization function in a wide wavelength range.

Such a polarizing plate 8 can be provided as an antireflection film in an organic EL display device. In this case, the polarizing plate 8 is usually provided so that the linear polarizing film 100, the electroconductive layer 30, the λ/2 substrate layer 52, the barrier layer 20, and the λ/4 substrate layer 51 are disposed in this order from the viewing side.

In the polarizing plate 8, at least one of the barrier layer 20 and the electroconductive layer 30 is provided so as to be in direct contact with at least one of the λ/4 substrate layer 51 and the λ/2 substrate layer 52, and preferably, both the barrier layer 20 and the electroconductive layer 30 are provided so as to be in direct contact with at least one of the λ/4 substrate layer 51 and the λ/2 substrate layer 52. For example, the barrier layer 20 may be in direct contact with the λ/4 substrate layer 51, and the electroconductive layer 30 may be in direct contact with the λ/2 substrate layer 52. As another example, both the barrier layer 20 and the electroconductive layer 30 may be in direct contact with the λ/2 substrate layer 52.

[9.9. Polarizing Plate as Ninth Embodiment]

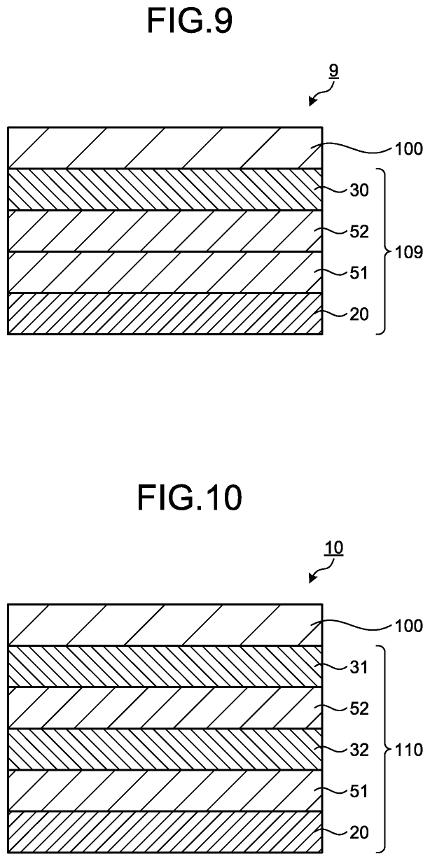

FIG. 9 is a cross-sectional view schematically illustrating a polarizing plate 9 as a ninth embodiment of the present invention.

As illustrated in FIG. 9, the polarizing plate 9 as the ninth embodiment of the present invention uses a multilayer film 109 different from those of the seventh embodiment and of the eighth embodiment in the order of layers. Specifically, the multilayer film 109 includes a barrier layer 20, a λ/4 substrate layer 51, a λ/2 substrate layer 52, and an electroconductive layer 30 in this order.

In the multilayer film 109, the angle formed between the slow axis of the λ/2 substrate layer 52 and the slow axis of the λ/4 substrate layer 51 is set to fall within the same particular range as that in the seventh embodiment. Thus, the combination of the λ/4 substrate layer 51 and the λ/2 substrate layer 52 makes the multilayer film 109 a broadband ¼ wave plate.

The surface of the multilayer film 109 on the electroconductive layer 30 side is bonded to the linear polarizing film 100. In this case, the bonding angle between the linear polarizing film 100 and the multilayer film 109 is set so that the angle formed between the polarized light transmission axis of the linear polarizing film 100 and the slow axis of the λ/2 substrate layer 52 falls within the same particular range as that in the seventh embodiment. The multilayer film 109 functions as a broadband ¼ wave plate, and thereby the polarizing plate 9 can exhibit an elliptical polarization function in a wide wavelength range.

Such a polarizing plate 9 can be provided as an antireflection film in an organic EL display device. In this case, the polarizing plate 9 is usually provided so that the linear polarizing film 100, the electroconductive layer 30, the λ/2 substrate layer 52, the λ/4 substrate layer 51, and the barrier layer 20 are disposed in this order from the viewing side.

In the polarizing plate 9, at least one of the barrier layer 20 and the electroconductive layer 30 is provided so as to be in direct contact with at least one of the λ/4 substrate layer 51 and the λ/2 substrate layer 52, and preferably, both the barrier layer 20 and the electroconductive layer 30 are provided so as to be in direct contact with at least one of the λ/4 substrate layer 51 and the λ/2 substrate layer 52. For example, the barrier layer 20 may be in direct contact with the λ/4 substrate layer 51, and the electroconductive layer 30 may be in direct contact with the λ/2 substrate layer 52.

[9.10. Polarizing Plate as Tenth Embodiment]

FIG. 10 is a cross-sectional view schematically illustrating a polarizing plate 10 as a tenth embodiment of the present invention.

As illustrated in FIG. 10, the polarizing plate 10 as the tenth embodiment of the present invention uses a multilayer film 110 including a first electroconductive layer 31 and a second electroconductive layer 32 as electroconductive layers. Specifically, the multilayer film 110 includes a barrier layer 20, a λ/4 substrate layer 51, the second electroconductive layer 32, a λ/2 substrate layer 52, and the first electroconductive layer 31 in this order.

In the multilayer film 110, the angle formed between the slow axis of the λ/2 substrate layer 52 and the slow axis of the λ/4 substrate layer 51 is set to fall within the same particular range as that in the seventh embodiment. Thus, the combination of the λ/4 substrate layer 51 and the λ/2 substrate layer 52 makes the multilayer film 110 a broadband ¼ wave plate.

The surface of the multilayer film 110 on the first electroconductive layer 31 side is bonded to the linear polarizing film 100. In this case, the bonding angle between the linear polarizing film 100 and the multilayer film 110 is set so that the angle formed between the polarized light transmission axis of the linear polarizing film 100 and the slow axis of the λ/2 substrate layer 52 falls within the same particular range as that in the seventh embodiment. The multilayer film 110 functions as a broadband ¼ wave plate, and thereby the polarizing plate 10 can exhibit an elliptical polarization function in a wide wavelength range.

Such a polarizing plate 10 can be provided as an antireflection film in an organic EL display device. In this case, the polarizing plate 10 is usually provided such that the linear polarizing film 100, the first electroconductive layer 31, the λ/2 substrate layer 52, the second electroconductive layer 32, the λ/4 substrate layer 51, and the barrier layer 20 are disposed in this order from the viewing side.

In this polarizing plate 10, at least one of the barrier layer 20 and the “first electroconductive layer 31 and second electroconductive layer 32” is provided so as to be in direct contact with at least one of the λ/4 substrate layer 51 and the λ/2 substrate layer 52. Thus, the barrier layer 20 may be in direct contact with at least one of the λ/4 substrate layer 51 and the λ/2 substrate layer 52. The first electroconductive layer 31 and the second electroconductive layer 32 may be in direct contact with at least one of the λ/4 substrate layer 51 and the λ/2 substrate layer 52. Further, all of the barrier layer 20, the first electroconductive layer 31, and the second electroconductive layer 32 may be in direct contact with at least one of the λ/4 substrate layer 51 and the λ/2 substrate layer 52. Preferably, both the barrier layer 20 and the “first electroconductive layer 31 and second electroconductive layer 32” are provided so as to be in direct contact with at least one of the λ/4 substrate layer 51 and the λ/2 substrate layer 52. For example, the barrier layer 20 and the second electroconductive layer 32 may be in direct contact with the λ/4 substrate layer 51, and the first electroconductive layer 31 may be in direct contact with the λ/2 substrate layer 52. As another example, the barrier layer 20 may be in direct contact with the λ/4 substrate layer 51, and the first electroconductive layer 31 and the second electroconductive layer 32 may be in direct contact with the λ/2 substrate layer 52.

[10. Antireflection Film]

The antireflection film according to the present invention includes the polarizing plate according to the present invention. The antireflection film according to the present invention may include an optional component in addition to the polarizing plate, and may include only the polarizing plate.

The antireflection film includes a linear polarizing film and a multilayer film. By providing the antireflection film on the display surface of an organic EL display device, it is possible to effectively prevent glare and outside light reflection on the display surface.

The ratio of reflectivity R₀ at an incident angle of 0° relative to reflectivity R_{10(0deg)} at an azimuth angle of 0° and an incident angle of 10°, that is, the ratio R₀/R_{10(0deg)} of the antireflection film is usually 0.95 or more and 1.05 or less. Further, the ratio of reflectivity R₀ at an incident angle of 0° relative to reflectivity R_{10(180deg)} at an azimuth angle of 180° and an incident angle of 10°, that is, the ratio R₀/R_{10(180deg)} of the antireflection film is usually 0.95 or more and 1.05 or less. The reflectivity R₀, the reflectivity R_{10(0deg)}, and the reflectivity R_{10(180deg)} may be measured using a spectrophotometer V7200 and an absolute reflectivity unit VAP7020 (manufactured by JASCO Corporation). When the antireflection film has such reflectivity ratios, highly-uniform antireflective effects can be obtained in both the front direction and the inclined direction at azimuth angles of 0° and 180°. In particular, excellent effects can be obtained in an organic EL display device having a curved surface. The antireflection film having such reflectivity ratios can be obtained by reducing the thickness of each of the members constituting the antireflection film and selecting flexible members. A direction as the reference of the azimuth angle (an azimuth angle of 0°) in the measurement of the reflectivity R_{10(0deg)} and the reflectivity R_{10(180deg)} may be any in-plane direction of the film. That is, when R₀, R_{10(0deg)} and R_{10(180deg)} satisfy the above-described requirement in a case where any one in-plane direction of a certain antireflection film is defined as the reference of the azimuth angle, the antireflection film can be regarded as one satisfying this requirement relating to reflectivity. It is particularly preferable that the requirement is satisfied when the direction of polarized light absorption axis of the linear polarizing film is the reference.

[11. Organic EL Display Device]

The organic EL display device according to the present invention includes the polarizing plate according to the present invention. Usually, this organic EL display device includes a light-emitting element and the polarizing plate. The light-emitting element usually includes an electrode for current application and a light-emitting layer containing a light-emitting material capable of emitting light by current application. The polarizing plate is provided so that the multilayer film and the linear polarizing film are disposed in this order from the light-emitting element side. Such an organic EL display device can display an image by light generated in the light-emitting element and passing through the polarizing plate.

It is preferable that the organic EL display device further includes a cover layer formed of a resin. Such a cover layer is usually provided so as to be closer to the viewing side than the polarizing plate, and plays the role of protecting the polarizing plate and the light-emitting element. The cover layer formed of a resin shows less brittleness than a cover glass, and therefore has higher resistance to bending. Therefore, the use of such a cover layer makes it possible to achieve a bendable organic EL display device.

The organic EL display device may further include a sealing material layer for sealing the light-emitting element, a wiring layer for applying current to the light-emitting element, and an adhesive layer or a tackiness layer for effecting adhesion or sticking of components included in the organic EL display device.

In a general organic EL display device, part of outside light that enters the display surface from the outside of the device may be reflected by a component in the device, such as a light-emitting element, and exit through the display surface. Such reflected light is recognized as glare or outside light reflection by an observer. On the other hand, the organic EL display device according to the present invention can prevent such glare or outside light reflection. Specifically, only linearly polarized light, which is part of light that enters from the outside of the device, passes through the linear polarizing film of the polarizing plate, and then passes through the multilayer film to be converted into elliptically polarized light. The elliptically polarized light is reflected by a component that reflects light in the display device, and again passes through the multilayer film to be converted into linearly polarized light having a polarizing axis in a direction not parallel to the polarizing axis of the incident linearly polarized light. As a result, reflected light that exits to the outside of the device is reduced, so that the function of antireflection is achieved.

### EXAMPLE

Hereinafter, the present invention will be specifically described by illustrating Examples. However, the present invention is not limited to the Examples described below. The present invention may be optionally modified for implementation without departing from the scope of claims of the present invention and its equivalents. In the following description, “%” and “part” representing quantity are on the basis of weight, unless otherwise specified. In the following description, “sccm” is a unit of flow rate of a gas. The amount of the gas flowing per minute is represented as the volume (cm³) of the gas at 25° C. and 1 atm.

[Evaluation Methods]

[Method for Measuring Hydrogenation Rate of Polymer]

The hydrogenation rate of a polymer was measured by ¹H-NMR at 145° C. using orthodichlorobenzene-d⁴ as a solvent.

[Method for Measuring Weight-Average Molecular Weight (Mw) and Number-Average Molecular Weight (Mn) of Polymer]

The weight-average molecular weight (Mw) and number-average molecular weight (Mn) of a polymer were measured as polystyrene equivalent values with the use of a gel permeation chromatography (GPC) system (“HLC-8320” manufactured by Tosoh Corporation). In the measurement, an H-type column (manufactured by Tosoh Corporation) was used as a column, and tetrahydrofuran was used as a solvent. The temperature during the measurement was 40° C.

[Method for Measuring Racemo Diad Ratio of Polymer]

The racemo diad ratio of a polymer was measured in the following manner.

¹³C-NMR measurement of the polymer was performed at 200° C. by an inverse-gated decoupling method using orthodichlorobenzene-d⁴ as a solvent. From the result of the ¹³C-NMR measurement, the racemo diad ratio of the polymer was determined on the basis of the intensity ratio between a signal at 43.35 ppm derived from meso diads and a signal at 43.43 ppm derived from racemo diads using the peak of orthodichorobenzene-d⁴ at 127.5 ppm as a reference shift.

[Method for Measuring Glass Transition Temperature Tg, Melting Point Tm, and Crystallization Peak Temperature Tpc of Polymer]

The glass transition temperature Tg and melting point Tm of a polymer were measured in the following manner.

First, a polymer was melted by heating, and the melted polymer was rapidly cooled with dry ice to obtain an amorphous polymer. Then, the amorphous polymer was used as a test specimen to measure the glass transition temperature Tg, melting point Tm, and crystallization peak temperature Tpc of the polymer with the use of a differential scanning calorimeter (DSC) at a temperature rise rate of 10° C./min (temperature rise mode).

[Method for Measuring Crystallization Degree of Polymer]

The crystallization degree (%) of a polymer was measured by an X-ray diffraction method.

[Method for Measuring Thickness of Film]

The thickness (μm) of a film was measured using a contact-type web thickness meter (“RC-101” manufactured by Maysun Corporation).

[Measurement of in-Plane Retardation Re of Film]

The in-plane retardation Re of a film was measured at a wavelength of 590 nm using a birefringence meter (“AxoScan” manufactured by Axometrix Corporation).

[Method for Measuring Inner Haze of Film]

The inner haze of a film was measured in the following manner.

First, a film was cut out to obtain a test specimen having a size of 50 mm×50 mm. Then, onto each of both surface of the test specimen, a cycloolefin film (“ZEONOR film ZF14-040” manufactured by ZEON Corporation, thickness: 40 μm) was bonded via a transparent optical tackiness film (“8146-2” manufactured by 3M Corporation) having a thickness of 50 μm to obtain a sample multilayer body having a layer structure of cycloolefin film/transparent optical tackiness film/test specimen/transparent optical tackiness film/cycloolefin film. Then, the haze of this sample multilayer body was measured using a haze meter (“NDH5000” manufactured by NIPPON DENSHOKU INDUSTRIES CO., LTD).

A reference layered body which included a cycloolefin film, a transparent optical tackiness film, a transparent optical tackiness film, and a cycloolefin film in this order was separately formed. Then, the haze of this reference layered body was measured with the above-described haze meter. The measured haze of the reference layered body was 0.04%. The haze of the reference layered body of 0.04% is a sum of the hazes of two cycloolefin films and hazes of two transparent optical tackiness films.

Then, from the haze of the sample multilayer body, 0.04% as a sum of the hazes of two cycloolefin films and the hazes of two transparent optical tackiness films was subtracted to determine the inner haze of the test specimen.

[Method for Measuring Thermal Size Change Rate of Film]

A film was cut out in an environment at a room temperature of 23° C. to provide a sample film of a square shape having a size of 150 mm×150 mm. This sample film was heated in an oven at 150° C. for 60 minutes and cooled to 23° C. (room temperature), and then the lengths of four edges and two diagonal lines of the sample film were measured.

On the basis of the measured length of each of the four edges, the thermal size change rate of the sample film was calculated by the following formula (I). In the formula (I), L_{A} (mm) represents the length of edge of the sample film after heating.

Thermal size change rate (%)=[(L_{A}−150)/150]×100 (I)

Further, on the basis of the measured lengths of the two diagonal lines, the thermal size change rate of the sample film was calculated by the following formula (II). In the formula (II), L_{D} (mm) represents the length of diagonal line of the sample film after heating.

Thermal size change rate (%)=[(L_{D}−212.13)/212.13]×100 (II)

Then, the value having maximum absolute value among the obtained six calculated values of the thermal size change rate was adopted as the thermal size change rate of the film.

[Method for Evaluating Chemical Resistance, Solvent Resistance, and Grease Resistance of Film]

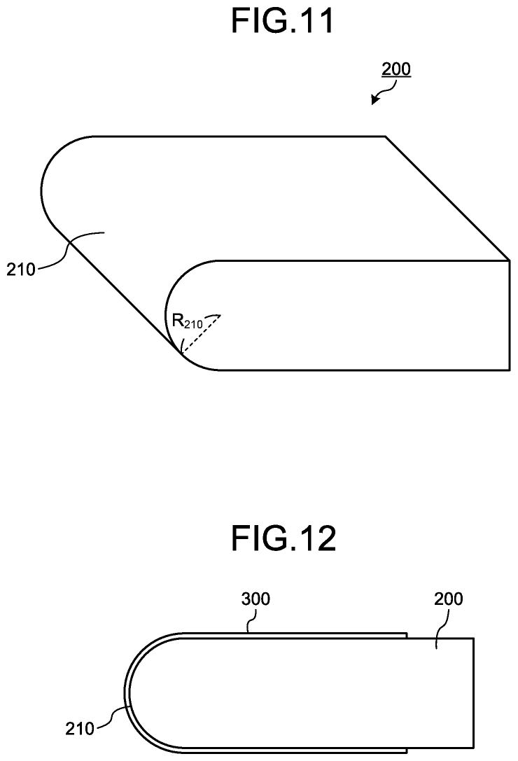

FIG. 11 is a perspective view schematically illustrating a jig 200 used in Examples according to the present invention and Comparative Examples.

As illustrated in FIG. 11, a plate-shaped jig 200 formed of stainless steel and having a thickness of 10 mm was prepared. This jig 200 has a semi-cylindrical curved surface 210 at its one end, and the curved surface 210 had a radius R₂₁₀ of 5 mm.

As reagents used as indicators of chemical resistance, 35% hydrochloric acid, 30% sulfuric acid, and a 30% aqueous sodium hydroxide solution were prepared. Further, as reagents used as indicators of solvent resistance, cyclohexane, normal hexane, methyl ethyl ketone, chloroform, and isopropanol were prepared. Further, as reagents used as indicators of grease resistance, oleic acid and Vaseline were prepared.

FIG. 12 is a front view schematically illustrating the jig 200 shown in FIG. 11 to which a film piece 300 is closely attached.

A film as a sample was cut to obtain a film piece having a width of 30 mm and a length of 100 mm. As illustrated in FIG. 12, the film piece 300 was bent so that its lengthwise direction was aligned along the semi-cylindrical curved surface 210 of the jig 200. Keeping the state of being closely attached to the jig 200, the film piece 300 was fixed.

Then, the jig 200, to which the film piece 300 was fixed, was immersed in each of the above-mentioned reagents other than Vaseline, allowed to stand at room temperature for 48 hours, and taken out from the reagent. Then, the film piece 300 was removed from the jig 200, wiped, and observed.

Separately, Vaseline was uniformly applied onto each of both surfaces of another film piece 300. Then, the film piece 300 onto which Vaseline had been applied was fixed to the jig 200 as illustrated in FIG. 12. The film piece 300 was allowed to stand at room temperature for 48 hours, removed from the jig 200, wiped to remove Vaseline attached thereto, and observed.

On the basis of the results of observation, the chemical resistance, solvent resistance, and grease resistance of the film were evaluated according to the following criteria.

“A”: Any of fracture, occurrence of cracking, whitening, discoloration, swelling, and deformation such as waving was not observed in the film piece.

“B”: Any of fracture, occurrence of cracking, whitening, discoloration, swelling, and deformation such as waving was observed in the film piece.

[Method for Evaluating Folding Resistance of Film (Folding Test)]

A film as a sample was subjected to a tension-free U-shape folding test for planar objects using a desktop model endurance test machine (“DLDMLH-FS” manufactured by Yuasa System Co., Ltd.). This test was performed by repeatedly folding the film under conditions of a width of 50 mm, a bending radius of 1 mm, and a folding speed of 80 cycles/min. The machine was stopped every 100 cycles until the number of folding cycles reached 1000 cycles, every 1000 cycles after the number of folding cycles exceeded 1000 cycles and until it reached 10,000 cycles, every 5000 cycles after the number of folding cycles exceeded 10,000 cycles and until it reached 50,000 cycles, and every 10,000 cycles after the number of folding cycles exceeded 50,000 cycles to visually observe the film. When the film was fractured, the number of folding cycles at that time was recorded as the “number of test cycles upto fracture”. Even when slight cracking was observed in the film, the film was evaluated as being “fractured”.

The above-described tension-free U-shape folding test for planar objects was performed five times on condition that the upper limit of the number of folding cycles was 200,000 cycles. Among the results of five times tests, the smallest number of test cycles upto fracture was used as an evaluation result.

[Method for Evaluating Bend Resistance of Film (Bending Test)]

A film as a sample was cut to have a width of 30 mm and a length of 300 mm. The cut film was subjected to a reciprocating repeated bending test using a desktop type endurance test machine (“TCDM111LH” manufactured by Yuasa System Co., Ltd.) under conditions of a bending radius of 5 mm, a bending angle of ±135°, and a load of 2 N. The machine was stopped every 100 cycles until the number of bending cycles reached 1000 cycles, every 1000 cycles after the number of bending cycles exceeded 1000 cycles and until it reached 10,000 cycles, every 5000 cycles after the number of bending cycles exceeded 10,000 cycles and until it reached 50,000 cycles, and every 10,000 cycles after the number of bending cycles exceeded 50,000 cycles to visually observe the film. When the film was fractured, the number of bending cycles at that time was recorded as the “number of test cycles upto fracture”. Even when slight cracking was observed in the film, the film was evaluated as being “fractured”.

The above-described test was performed five times on condition that the upper limit of the number of bending cycles was 200,000 cycles. Among the results of five times tests, the smallest number of test cycles upto fracture was used as an evaluation result.

[Tensile Elastic Modulus of Film]

The tensile elastic modulus of a film was measured in accordance with JIS K 7113 using a tension tester under conditions of a temperature of 23° C., a humidity of 60±5% RH, a distance between chucks of 115 mm and a tension speed of 100 mm/min.

[Method for Evaluating Film Formation Suitability of Electroconductive Layer]

The surface condition of a multilayer film was observed, and film formation suitability was evaluated according to the following criteria.

“Good”: Deformation such as wrinkling or waving was not observed on the film surface.

“Poor”: Deformation such as wrinkling or waving was observed on the film surface.

[Method for Evaluating Change in Electric Continuity of Multilayer Film after Folding Test]

A multilayer film was subjected to the above-described tension-free U-shape folding test for planar objects until the number of folding cycles reached 200,000 times. On the basis of the resistance value R(0) [Ω/sq.] of an electroconductive layer before test and the resistance value R(1) [Ω/sq.] of the electroconductive layer after test, the change rate ΔR of resistance value was calculated by the formula: ΔR={R(1)−R(0)}/R(0). The resistance values were measured using a resistivity meter (“Loresta GX MCP-T700” manufactured by Mitsubishi Chemical Analytech Co., Ltd.).

[Method for Measuring Water Vapor Transmission Rate of Multilayer Film]

A water vapor transmission rate was measured using a water vapor transmission rate meter (“PERMATRAN-W” manufactured by MOCON Corporation) in accordance with JIS K 7129 B-1992 under conditions of a temperature of 40° C. and 90% RH. The detection limit of this meter is 0.01 g/(m²·day).

[Method for Measuring Reflectivity Ratios of Antireflection Film]

The surface of a multilayer film on the side opposite to a barrier layer and a linear polarizing film consisting of a polyvinyl alcohol resin were bonded together to obtain a circular polarizing plate for testing. The obtained circular polarizing plate was subjected to measurement of reflectivity R₀ at an incident angle of 0°, measurement of reflectivity R_{10(0deg)} at an azimuth angle of 0° and an incident angle of 10°, and measurement of reflectivity R_{10(180deg)} at an azimuth angle of 180° and an incident angle of 10° in the following manner.

The circular polarizing plate was cut to have an appropriate size, and the barrier layer-side surface of the circular polarizing plate and the reflecting surface of a reflector (trade name “Metalmy TS50” manufactured by Toray Industries Inc., aluminum-vapor deposited PET (polyethylene terephthalate) film) were bonded together. The bonding was performed via a tackiness agent layer (trade name “CS9621” manufactured by Nitto Denko Corporation). In this way, a layered body for evaluation having a layer structure of circular polarizing plate/tackiness agent layer/reflector was obtained. The obtained layered body for evaluation was measured for the reflectivity of light incident on the circular polarizing plate. The measurement was performed using a spectrophotometer V7200 and an absolute reflectivity unit VAP7020 (manufactured by JASCO Corporation). At the time of measurement, the reference of the azimuth angle was the direction of polarized light absorption axis of the linear polarizing film when the layered body for evaluation was observed from the circular polarizing plate side, and a reflectivity R₀ at an incident angle of 0°, a reflectivity R_{10(0deg)} at an azimuth angle of 0° and an incident angle of 10° and a reflectivity R_{10(180deg)} at an azimuth angle of 180° and an incident angle of 10° were measured. From the thus obtained reflectivities, a reflectivity ratio R₀/R_{10(0deg)} and a reflectivity ratio R₀/R_{10(180deg)} were determined.

[Method for Evaluating Color Unevenness in Organic EL Display Device]

The λ/2 substrate layer-side surface of a multilayer film and a linear polarizing film consisting of a polyvinyl alcohol resin were bonded together to obtain a circular polarizing plate for testing. The bonding was performed so that an angle between the slow axis of the λ/4 substrate layer of the multilayer film and the polarized light transmission axis of the linear polarizing film was 15°, and an angle between the slow axis of the λ/2 substrate layer of the multilayer film and the polarized light transmission axis of the linear polarizing film was 75°.

A commercially-available smartphone (“GFlex LGL23” manufactured by LG Electronics) including an organic EL display device was disassembled, and a circular polarizing plate originally provided on the display surface of the smartphone was removed. Instead of the removed circular polarizing plate, the above-described circular polarizing plate for testing was installed in the smartphone to obtain an organic EL display device for testing. The circular polarizing plate for testing was installed so that the linear polarizing film and the multilayer film were disposed in this order from the viewing side. The luminance of this display device in a black display state and that in a white display state were measured and found to be 5.1 cd/m² and 300 cd/m², respectively. The display surface of the display device in a black display state was visually observed from an inclined direction (polar angle: 45°, all azimuths) under outside light on a fine day, and the presence or absence of color unevenness was evaluated.

### Production Example 1. Production of Hydrogenated Product of Ring-Opening Polymer of Dicyclopentadiene

A hydrogenated product of a ring-opening polymer of dicyclopentadiene was produced in the following manner.

A metallic pressure-resistant reaction vessel was sufficiently dried. Then, the atmosphere in the vessel was replaced with nitrogen. Into this pressure-resistant reaction vessel, 154.5 parts of cyclohexane, 42.8 parts (30 parts as the dicyclopentadene content) of a 70% cyclohexane solution of dicyclopentadene (endo-isomer content: 99% or more), and 1.8 parts of 1-hexene were added. The mixture was heated to 53° C.

Into a solution obtained by dissolving 0.014 part of tetrachlorotungsten phenylimide(tetrahydrofuran) complex in 0.70 part of toluene, 0.061 part of a 19% n-hexane solution of diethylaluminum ethoxide was added. The mixture was stirred for 10 minutes to prepare a catalyst solution. The catalyst solution was added to the pressure-resistant reaction vessel to initiate a ring-opening polymerization reaction. Then, the reaction was performed for 4 hours while maintaining the temperature at 53° C. to obtain a solution of a ring-opening polymer of dicyclopentadiene.

The number-average molecular weight (Mn) and weight-average molecular weight (Mw) of the obtained ring-opening polymer of dicyclopentadiene were 8,830 and 29,800, respectively. The molecular weight distribution (Mw/Mn) determined from these weights was 3.37.

Into 200 parts of the obtained solution of the ring-opening polymer of dicyclopentadiene, 0.037 part of 1,2-ethanediol was added as a terminator. The mixture was heated to 60° C. and stirred for 1 hour to terminate the polymerization reaction. To the resultant product, 1 part of a hydrotalcite-like compound (“KYOWAAD (registered trademark) 2000” manufactured by Kyowa Chemical Industry Co., Ltd.) was added. The mixture was heated to 60° C. and stirred for 1 hour. Then, 0.4 part of a filter aid (“Radiolite (registered trademark) #1500” manufactured by Showa Chemical Industry Co., Ltd.) was added. The mixture was filtered through a PP pleated cartridge filter (“TCP-HX” manufactured by Advantec Toyo kaisha, Ltd.) to separate the adsorbent and the solution.

Into 200 parts (amount of polymer: 30 parts) of the solution of the ring-opening polymer of dicyclopentadiene after filtration, 100 parts of cyclohexane was added, and 0.0043 part of chlorohydridocarbonyltris(triphenylphosphine)ruthenium was further added. Then a hydrogenation reaction was performed at a hydrogen pressure of 6 MPa and 180° C. for 4 hours. In this way, a reaction liquid containing a hydrogenated product of the ring-opening polymer of dicyclopentadiene was obtained. This reaction liquid was a slurry solution in which the hydrogenated product was precipitated.

The hydrogenated product and the solution contained in the reaction liquid were separated using a centrifugal separator, and dried under reduced pressure at 60° C. for 24 hours to obtain 28.5 parts of the hydrogenated product of the ring-opening polymer of dicyclopentadiene having crystallizability. The hydrogenation rate of the hydrogenated product was found to be 99% or more. The hydrogenated product had a glass transition temperature Tg of 97° C., a melting point Tm of 266° C., a crystallization peak temperature Tpc of 136° C., and a racemo⋅diad ratio of 89%.

Then, to 100 parts of the obtained hydrogenated product of the ring-opening polymer of dicyclopentadiene, 1.1 parts of an antioxidant (tetrakis[methylene-3-(3′,5′-di-t-butyl-4′-hydroxyphenyl)propionate]methane; “Irganox (registered trademark) 1010” manufactured by BASF Japan) was added. The mixture was fed into a twin screw extruder (“TEM-37B” manufactured by TOSHIBA MACHINE CO., LTD.) having four die holes with an inner diameter of 3 mmΦ. With the above-described twin screw extruder, the resin was molded into a strand-shaped molded product by hot melt-extrusion molding. The molded product was finely cut with a strand cutter to obtain resin pellets. The above-described twin screw extruder was operated under the following conditions.
Barrel set temperature: 270° C. to 280° C.
Die set temperature: 250° C.
Screw rotation speed: 145 rpm
Feeder rotation speed: 50 rpm

### Production Example 2. Production of Primary Film 1

The resin pellets obtained in Production Example 1 were supplied to a hot melt-extrusion film molding machine including a T-die. Using this film molding machine, the resin was extruded through the T-die and wound around a roll at a speed of 20 m/min. In this way, a long-length primary film 1 (width: 1340 mm) was produced. The above-described film molding machine was operated under the following conditions.
Barrel set temperature: 280° C. to 290° C.
Die temperature: 270° C.

The obtained primary film 1 had a thickness of 20 μm.

### Production Example 3. Production of Primary Film 2

A long-length primary film 2 was produced by the same manner as that of Production Example 2 except that the roll winding speed was changed to 8 m/min. The obtained primary film 2 had a thickness of 50 μm.

### Production Example 4. Production of Primary Film 3

A long-length primary film 3 was produced by the same manner as that of Production Example 2 except that the roll winding speed was changed to 10 m/min. The obtained primary film 3 had a thickness of 50 μm.

### Production Example 5. Production of Stretched Film 1

The primary film 1 obtained in Production Example 2 was supplied to a tenter stretching machine including clips. Both the widthwise ends of the film were gripped by the clips of the tenter stretching machine, and the film was stretched in the TD direction under conditions of a stretching temperature of 125° C. and a stretching ratio of 1.33 times. Then, the film was passed through an oven at 170° C. for 30 seconds while the width between the clips was remained fixed to perform crystallization treatment. Then, both the widthwise ends of the film were cut to obtain a stretched film 1 having a width of 1300 mm and a thickness of 15 μm. The obtained stretched film 1 had an in-plane retardation Re of 0.8 nm, a thickness-direction retardation Rth of 16.9 nm, a crystallization degree of 43%, an inner haze of 0.1%, and a tensile elastic modulus of 2800 MPa, and the thermal size change rate in the plane of the film when the film was heated at 150° C. for 1 hour was 0.03%.

The obtained stretched film 1 was evaluated for its chemical resistance, solvent resistance, grease resistance, folding resistance, and bend resistance by the above-described methods. The results are shown in the following Tables 1 and 2.

### Production Example 6. Production of Unstretched Film 1

Pellets of a norbornene-based resin (“ZEONOR1600” manufactured by ZEON Corporation) were dried at 100° C. for 5 hours. After dried, the pellets were supplied to an extruder, passed through a polymer filter, extruded through a T-die into a sheet shape on a casting drum, and cooled to obtain an unstretched film 1 having a thickness of 25 The obtained unstretched film 1 had an in-plane retardation Re of 3.2 nm and a thickness-direction retardation Rth of 6.7 nm.

The obtained unstretched film 1 was evaluated for its chemical resistance, solvent resistance, grease resistance, folding resistance, and bend resistance by the above-described methods. The results are shown in the following Tables 1 and 2.

TABLE 1
[chemical resistance, solvent resistance and grease resistance
of the stretched film 1 and the unstretched film 1]

| | Stretched film 1 | Unstretched film 1 |
|---|---|---|
| | (Production | (Production |
| Reagent | Example 5) | Example 6) |
| 35% Hydrochloric acid | A | A |
| 30% Sulfuric acid | A | A |
| 30% Aqueous sodium | A | A |
| hydroxide solution | | |
| Cyclohexane | A | B |
| Normal hexane | A | B |
| Chloroform | A | B |
| Isopropanol | A | A |
| Methyl ethyl ketone | A | A |
| Oleic acid | A | B |
| Vaseline | A | B |

TABLE 2
[folding resistance and bend resistance of
the stretched film 1 and the unstretched film 1]

| | | Folding test | Bending test |
|---|---|---|---|
| | | number of test | number of test |
| | Thickness | cycles upto | cycles upto |
| | (μm) | fracture (cycles) | fracture (cycles) |
| Stretched Film 1 | 15 | 200,000 or more | 200,000 or more |
| (Production | | | |
| Example 5) | | | |
| Unstretched Film 1 | 25 | 90,000 | 40,000 |
| (Production | | | |
| Example 6) | | | |

### PRODUCTION Example 7: Production of ½ Wave Film 1

The primary film 2 obtained in Production Example 3 was supplied to a roll-type longitudinal stretching machine and subjected to a longitudinal uniaxial stretching treatment to stretch the film in the lengthwise direction at a temperature of 120° C. and a ratio of 2.3 times. Then, the film was passed through an oven at 170° C. for 30 seconds to perform crystallization treatment. Then, both the widthwise ends of the film were cut to obtain a ½ wave film 1 having a width of 780 mm and a thickness of 33 The obtained ½ wave film 1 had an in-plane retardation Re of 270 nm, a thickness-direction retardation Rth of 135 nm, a crystallization degree of 46%, an inner haze of 0.2%, and a tensile elastic modulus of 2850 MPa, and the thermal size change rate in the plane of the film when the film was heated at 150° C. for 1 hour was 0.1%.

### Production Example 8: Production of ¼ Wave Film 1

The primary film 3 obtained in Production Example 4 was supplied to a roll-type longitudinal stretching machine and subjected to a longitudinal uniaxial stretching treatment to stretch the film in the lengthwise direction at a temperature of 125° C. and a ratio of 2.0 times. Then, the film was passed through an oven at 170° C. for 30 seconds to perform crystallization treatment. Then, both the widthwise ends of the film were cut to obtain a ¼ wave film 1 having a width of 880 mm and a thickness of 28 μm. The obtained ¼ wave film 1 had an in-plane retardation Re of 140 nm, a thickness-direction retardation Rth of 70 nm, a crystallization degree of 44%, an inner haze of 0.2%, and a tensile elastic modulus of 2800 MPa, and the thermal size change rate in the plane of the film when the film was heated at 150° C. for 1 hour was 0.1%.

### Production Example 9: Production of ½ Wave Film 2

Pellets of a norbornene-based resin (“ZEONOR1430” manufactured by ZEON Corporation) were dried at 100° C. for 5 hours. After dried, the pellets were supplied to an extruder, passed through a polymer filter, extruded through a T-die into a sheet shape on a casting drum, and cooled to obtain an unstretched film 2 having a thickness of 50 μm.

This unstretched film 2 was supplied to a roll-type longitudinal stretching machine and subjected to a longitudinal uniaxial stretching treatment to stretch the film in the lengthwise direction at a temperature of 136° C. and a ratio of 2.3 times, so that a ½ wave film 2 having a thickness of 33 μm was obtained. The obtained ½ wave film 2 had an in-plane retardation Re of 270 nm and a thickness-direction retardation Rth of 135 nm.

### Production Example 10: Production of ¼ Wave Film 2

Pellets of a norbornene-based resin (“ZEONOR1430” manufactured by ZEON Corporation) were dried at 100° C. for 5 hours. After dried, the pellets were supplied to an extruder, passed through a polymer filter, extruded through a T-die into a sheet shape on a casting drum, and cooled to obtain an unstretched film 3 having a thickness of 40 μm.

This unstretched film 3 was supplied to a roll-type longitudinal stretching machine and subjected to a longitudinal uniaxial stretching treatment to stretch the film in the lengthwise direction at a temperature of 139° C. and a ratio of 2.0 times, so that a ¼ wave film 2 having a thickness of 28 μm was obtained. The obtained ¼ wave film 2 had an in-plane retardation Re of 140 nm and a thickness-direction retardation Rth of 70 nm.

### Example 1

(1-1. Formation of Barrier Layer)

The stretched film 1 obtained in Production Example 5 was prepared as a substrate layer. On the surface of the substrate layer, a barrier layer was formed by a CVD method.

The operation of formation of the barrier layer was performed using a film winding-type plasma CVD apparatus. The formation of the barrier layer was performed by RF plasma discharge under forming conditions of a tetramethylsilane (TMS) flow rate of 10 sccm, an oxygen (O₂) flow rate of 100 sccm, an output of 0.8 kW, a total pressure of 5 Pa, and a film conveyance speed of 0.5 m/min. As a result, the barrier layer consisting of SiOx and having a thickness of 300 nm was formed on one surface of the substrate layer, so that an intermediate film 1 having a layer structure of substrate layer/barrier layer was obtained.

(1-2. Formation of Electroconductive Layer (Sputtering Process))

On the substrate layer-side surface of the intermediate film 1 obtained in the above-described step (1-1), an electroconductive layer was formed. The operation of formation of the electroconductive layer was performed using a film winding-type magnetron sputtering apparatus. As a sputtering target, an In₂O₃—SnO₂ ceramic target was used. Other forming conditions were an argon (Ar) flow rate of 150 sccm, an oxygen (O₂) flow rate of 10 sccm, an output of 4.0 kW, a vacuum degree of 0.3 Pa, and a film conveyance speed of 0.5 m/min. As a result, the electroconductive layer consisting of ITO and having a thickness of 100 nm was formed on the surface of the substrate layer, so that a multilayer film having a layer structure of electroconductive layer/substrate layer/barrier layer was obtained.

The obtained multilayer film was evaluated for its chemical resistance, solvent resistance, grease resistance, film formation suitability of electroconductive layer, and change in electric continuity after folding test by the above-described methods. Further, the water vapor transmission rate of the multilayer film was measured and found to be equal to or less than the detection limit {0.01 g/(m²·day)} of the meter. Further, an antireflection film was produced using this multilayer film by the above-described method, and the reflectivity ratio R₀/R_{10(0deg)} and the reflectivity ratio R₀/R_{10(180deg)} of the antireflection film were determined and found to be R₀/R_{10(0deg)}=0.87 and R₀/R_{10(180deg)}=0.85, respectively.

### Comparative Example 1

The unstretched film 1 obtained in Production Example 6 was used instead of the stretched film 1 obtained in Production Example 5. In the same manner as in Example 1 except for the aforementioned matters, a multilayer film was produced and evaluated.

### Example 2

(2-1. Production of Intermediate Film 2 Including Barrier Layer)

The ¼ wave film 1 obtained in Production Example 8 was prepared as a λ/4 substrate layer. On the surface of the λ/4 substrate layer, a barrier layer was formed by a CVD method. The operation of formation of the barrier layer was performed by the same manner as that of the step (1-1) in Example 1. As a result, the barrier layer consisting of SiOx and having a thickness of 300 nm was formed on one surface of the λ/4 substrate layer, so that an intermediate film 2 having a layer structure of λ/4 substrate layer/barrier layer was obtained.

(2-2. Production of Intermediate Film 3 Including Electroconductive Layer)

The ½ wave film 1 obtained in Production Example 7 was prepared as a λ/2 substrate layer. On the surface of the λ/2 substrate layer, an electroconductive layer was formed. The operation of formation of the electroconductive layer was performed by the same manner as that of the step (1-2) in Example 1. As a result, the electroconductive layer consisting of ITO and having a thickness of 100 nm was formed on the surface of the λ/2 substrate layer, so that an intermediate film 3 having a layer structure of electroconductive layer/λ/2 substrate layer was obtained.

(2-3. Bonding)

The λ/4 substrate layer-side surface of the intermediate film 2 and the electroconductive layer-side surface of the intermediate film 3 were bonded together via a layer of a tackiness agent (“CS9621T” manufactured by Nitto Denko Corporation). The thickness of the layer of the tackiness agent was 20 The bonding was performed so that an angle between the slow axis of the λ/4 substrate layer and the slow axis of the λ/2 substrate layer was 60° when viewed in the thickness direction. In this way, a multilayer film having a layer structure of barrier layer/λ/4 substrate layer/tackiness agent layer/electroconductive layer/λ/2 substrate layer was obtained.

The obtained multilayer film was evaluated for its chemical resistance, solvent resistance, grease resistance, film formation suitability of electroconductive layer, and color unevenness in an organic EL display device by the above-described methods. Further, the water vapor transmission rate of the multilayer film was measured and found to be equal to or less than the detection limit {0.01 g/(m²·day)} of the meter. Further, an antireflection film was produced using this multilayer film by the above-described method, and the reflectivity ratio R₀/R_{10(0deg)} and the reflectivity ratio R₀/R_{10(180deg)} of the antireflection film were determined and found to be R₀/R_{10(0deg)}=1.00 and R₀/R_{10(180deg)}=1.00 respectively.

### Comparative Example 2

The ¼ wave film 2 obtained in Production Example 10 was used instead of the ¼ wave film 1 obtained in Production Example 8. The ½ wave film 2 obtained in Production Example 9 was used instead of the ½ wave film 1 obtained in Production Example 7. In the same manner as in Example 2 except for the aforementioned matters, a multilayer film was produced and evaluated.

### Results of Examples and Comparative Examples

The results of the above-described Examples and Comparative Examples are shown in the following Table 3.

TABLE 3
[Results of Examples and Comparative Examples]

| | | Ex. 1 | Comp. Ex. 1 | Ex. 2 | Comp. Ex. 2 |
|---|---|---|---|---|---|
| Chemical | 35% Hydrochloric acid | A | A | A | A |
| resistance | 30% Sulfuric acid | A | A | A | A |
| | 30% Aqueous sodium | A | A | A | A |
| | hydroxide solution | | | | |
| Solvent | Cyclohexane | A | B | A | B |
| resistance | Normal hexane | A | B | A | B |
| | Chloroform | A | B | A | B |
| | Isopropanol | A | A | A | A |
| | Methyl ethyl ketone | A | A | A | A |
| Grease | Oleic acid | A | B | A | B |
| resistance | Vaseline | A | B | A | B |

| | | | | |
|---|---|---|---|---|
| Film formation suitability | Good | Poor | Good | Poor |
| of electroconductive layer | | | | |
| Change in electric continuity | 30% or lower | Evaluation cannot | not evaluated | not evaluated |
| after folding test | | be performed | | |
| | | for fracture | | |
| | | of the film | | |
| Color unevenness in | not evaluated | not evaluated | Unevenness | Unevenness |
| an organic EL display device | | | does not present | presents |

### REFERENCE SIGN LIST

1-10 polarizing plate
100 linear polarizing film
101-110 multilayer film
10, 11 and 12 low-Re substrate layer
20 barrier layer
30 electroconductive layer
31 first electroconductive layer
32 second electroconductive layer
40 ¼ wave film layer
50 and 51 λ/4 substrate layer
52 λ/2 substrate layer
200 jig
210 curved surface
300 film piece

1. A multilayer film for an organic electroluminescent display device, comprising at least one substrate layer containing a crystallizable polymer, a barrier layer, and an electroconductive layer, wherein
at least one of the barrier layer and the electroconductive layer is in direct contact with the substrate layer.

2. The multilayer film according to claim 1, wherein both the barrier layer and the electroconductive layer are in direct contact with the substrate layer.

3. The multilayer film according to claim 1, wherein a melting point of the crystallizable polymer is 250° C. or higher.

4. The multilayer film according to claim 1, wherein the crystallizable polymer contains an alicyclic structure.

5. The multilayer film according to claim 1, wherein the crystallizable polymer is a hydrogenated product of a ring-opening polymer of dicyclopentadiene.

6. The multilayer film according to claim 1, wherein the crystallizable polymer has a positive intrinsic birefringence value.

7. The multilayer film according to claim 1, wherein the multilayer film includes one or more inorganic barrier layers as the barrier layer.

8. The multilayer film according to claim 1, wherein a water vapor transmission rate of the multilayer film is 0.01 g/(m²·day) or less.

9. The multilayer film according to claim 1, wherein the multilayer film includes one or more organic electroconductive layers as the electroconductive layer.

10. The multilayer film according to claim 9, wherein the organic electroconductive layer contains polyethylenedioxythiophene.

11. The multilayer film according to claim 1, wherein the multilayer film includes one or more inorganic electroconductive layers as the electroconductive layer.

12. The multilayer film according to claim 11, wherein the inorganic electroconductive layer contains at least one selected from the group consisting of Ag, Cu, ITO, and metallic nanowires.

13. The multilayer film according to claim 1, wherein, when the substrate layer is heated at 150° C. for 1 hour, an absolute value of a thermal size change rate in a plane of a film of the substrate layer is 1% or less.

14. The multilayer film according to claim 1, wherein
the multilayer film includes a high-Re substrate layer, of which an in-plane retardation Re at a temperature of 23° C. and a measurement wavelength of 590 nm is 100 nm or more and 300 nm or less, as the substrate layer, and
an absolute value of photoelastic coefficient of the high-Re substrate layer is 2.0×10⁻¹¹ Pa⁻¹ or less.

15. The multilayer film according to claim 14, wherein
the multilayer film has a long-length shape, and
a slow axis of the high-Re substrate layer is present in an oblique direction relative to a lengthwise direction of the multilayer film.

16. The multilayer film according to claim 14, wherein a birefringence Δn of the high-Re substrate layer is 0.0010 or more.

17. The multilayer film according to claim 1, wherein
the multilayer film includes a low-Re substrate layer, of which an in-plane retardation Re at a temperature of 23° C. and a measurement wavelength of 590 nm is less than 100 nm, as the substrate layer, and
an absolute value of photoelastic coefficient of the low-Re substrate layer is 2.0×10⁻¹¹ Pa⁻¹ or less.

18. The multilayer film according to claim 17, wherein
the multilayer film has a long-length shape,
the multilayer film includes a long-length ¼ wave film layer, and
a slow axis of the ¼ wave film layer is present in an oblique direction relative to a lengthwise direction of the multilayer film.

19. A polarizing plate comprising the multilayer film according to claim 1, and a linear polarizing film.

20. The polarizing plate according to claim 19, wherein the multilayer film functions as a protective layer for the linear polarizing film.

21. The polarizing plate according to claim 19, wherein
the multilayer film includes a λ/4 substrate layer having an in-plane retardation of ¼ wavelength as the substrate layer,
the polarizing plate includes the linear polarizing film, the electroconductive layer, the λ/4 substrate layer, and the barrier layer in this order, and
an angle formed between a polarized light transmission axis of the linear polarizing film and a slow axis of the λ/4 substrate layer is 35° or more and 55° or less.

22. The polarizing plate according to claim 19, wherein
the multilayer film includes a λ/4 substrate layer having an in-plane retardation of ¼ wavelength and a λ/2 substrate layer having an in-plane retardation of ½ wavelength as the substrate layer,
the polarizing plate includes the linear polarizing film, the λ/2 substrate layer, the electroconductive layer, the λ/4 substrate layer, and the barrier layer in this order,
an angle formed between a polarized light transmission axis of the linear polarizing film and a slow axis of the λ/2 substrate layer is 10° or more and 20° or less, or 70° or more and 80° or less, and
an angle formed between the slow axis of the λ/2 substrate layer and a slow axis of the λ/4 substrate layer is 55° or more and 65° or less.

23. The polarizing plate according to claim 22, wherein
the λ/2 substrate layer and the electroconductive layer are in direct contact with each other, and
the λ/4 substrate layer and the barrier layer are in direct contact with each other.

24. The polarizing plate according to claim 22, wherein
the λ/4 substrate layer and the electroconductive layer are in direct contact with each other, and
the λ/4 substrate layer and the barrier layer are in direct contact with each other.

25. The polarizing plate according to claim 19, wherein
the multilayer film includes a λ/4 substrate layer having an in-plane retardation of ¼ wavelength and a λ/2 substrate layer having an in-plane retardation of ½ wavelength as the substrate layer,
the polarizing plate includes the linear polarizing film, the electroconductive layer, the λ/2 substrate layer, the barrier layer, and the λ/4 substrate layer in this order,
an angle formed between a polarized light transmission axis of the linear polarizing film and a slow axis of the λ/2 substrate layer is 10° or more and 20° or less, or 70° or more and 80° or less, and
an angle formed between the slow axis of the λ/2 substrate layer and a slow axis of the λ/4 substrate layer is 55° or more and 65° or less.

26. The polarizing plate according to claim 25, wherein
the λ/2 substrate layer and the electroconductive layer are in direct contact with each other, and
the λ/4 substrate layer and the barrier layer are in direct contact with each other.

27. The polarizing plate according to claim 25, wherein
the λ/2 substrate layer and the electroconductive layer are in direct contact with each other, and
the λ/2 substrate layer and the barrier layer are in direct contact with each other.

28. The polarizing plate according to claim 19, wherein
the multilayer film includes a λ/4 substrate layer having an in-plane retardation of ¼ wavelength and a λ/2 substrate layer having an in-plane retardation of ½ wavelength as the substrate layer,
the polarizing plate includes the linear polarizing film, the electroconductive layer, the λ/2 substrate layer, the λ/4 substrate layer, and the barrier layer in this order,
an angle formed between a polarized light transmission axis of the linear polarizing film and a slow axis of the λ/2 substrate layer is 10° or more and 20° or less, or 70° or more and 80° or less, and
an angle formed between the slow axis of the λ/2 substrate layer and a slow axis of the λ/4 substrate layer is 55° or more and 65° or less.

29. The polarizing plate according to claim 19, wherein the multilayer film include a first electroconductive layer and a second electroconductive layer as the electroconductive layer.

30. The polarizing plate according to claim 29, wherein
the multilayer film includes a λ/4 substrate layer having an in-plane retardation of ¼ wavelength and a λ/2 substrate layer having an in-plane retardation of ½ wavelength as the substrate layer,
the polarizing plate includes the linear polarizing film, the first electroconductive layer, the λ/2 substrate layer, the second electroconductive layer, the λ/4 substrate layer, and the barrier layer in this order,
an angle formed between a polarized light transmission axis of the linear polarizing film and a slow axis of the λ/2 substrate layer is 10° or more and 20° or less, or 70° or more and 80° or less, and
an angle formed between the slow axis of the λ/2 substrate layer and a slow axis of the λ/4 substrate layer is 55° or more and 65° or less.

31. The polarizing plate according to claim 30, wherein
the λ/2 substrate layer and the first electroconductive layer are in direct contact with each other,
the λ/4 substrate layer and the second electroconductive layer are in direct contact with each other, and
the λ/4 substrate layer and the barrier layer are in direct contact with each other.

32. The polarizing plate according to claim 30, wherein
the λ/2 substrate layer and the first electroconductive layer are in direct contact with each other,
the λ/2 substrate layer and the second electroconductive layer are in direct contact with each other, and
the λ/4 substrate layer and the barrier layer are in direct contact with each other.

33. The polarizing plate according to claim 22, wherein
the polarizing plate has a long-length shape,
the polarized light transmission axis of the linear polarizing film is parallel to a lengthwise direction of the polarizing plate, and
the slow axis of the λ/2 substrate layer or the λ/4 substrate layer is present in an oblique direction relative to the lengthwise direction of the polarizing plate.

34. An antireflection film comprising the polarizing plate according to claim 19, wherein
a ratio R₀/R_{10(0deg)} of reflectivity R₀ at an incident angle of 0° relative to reflectivity R_{10(0deg)} at an azimuth angle of 0° and an incident angle of 10° is 0.95 or more and 1.05 or less, and
a ratio R₀/R_{10(180deg)} of the reflectivity R₀ at the incident angle of 0° relative to reflectivity R_{10(180deg)} at an azimuth angle of 180° and an incident angle of 10° is 0.95 or more and 1.05 or less.

35. An organic electroluminescent display device comprising the polarizing plate according to claim 19.

36. The organic electroluminescent display device according to claim 35, comprising a cover layer formed of a resin.
